(19) United States
(12) Patent Application Publication
(10) Pub. No.: US 2026/0352229 A1
(43) Pub. Date: Nov. 5, 2026

(54) METHOD AND SYSTEM FOR IMPROVED LEMPEL-ZIV (LZ) COMPRESSION

(71) Applicant: QUALCOMM Incorporated, San Diego, CA (US)

(72) Inventors: Andrew Edmund TURNER, San Diego, CA (US); Hyung Joon KIM, San Diego, CA (US); Huai-Nan PENG, Miaoli City (TW); Tomer Rafael BEN-CHEN, Amikam (IL); David TEB, Haifa (IL)

(21) Appl. No.: 19/482,399

(22) PCT Filed: May 7, 2024
(86) PCT No.: PCT/US2024/028111

§ 371 Date: Nov. 7, 2025

(30) Foreign Application Priority Data
Jun. 20, 2023 (IL) 303889

(51) Int. Cl. H03M 7/40; H03M 7/30

(52) U.S. Cl. CPC H03M 7/4037; H03M 7/3082; H03M 7/6011

(57) ABSTRACT

Methods and computing devices configured to perform enhanced coding operations (e.g., compression, decompression, LZ-based compression techniques, etc.). A computing device processing system may be configured to receive an input data stream, query a search table with sequences of bytes (or characters, symbols, etc.) in the received input data stream to receive one or more location vectors for each byte, query a match table with the received location vectors to identify the starts and ends of matching sequences, and perform a history buffer check in response to determining that a match failed in the match table. The computing device processing system may determine copy and literal commands for the input data stream based on heuristics and the results of the queries to the search table, the match table, or the history buffer, and perform enhanced Huffman coding operations to encode the copy and literal commands into a compressed bitstream.

### RELATED APPLICATIONS

This application claims the benefit of priority from Israel Provisional Application No. 303889, filed Jun. 20, 2023; the entire contents of which is herein incorporated by reference.

### BACKGROUND

Modern computing devices use data compression techniques to reduce the size of data. Compression techniques are particularly important in processing systems that transmit, receive, or store large amounts of data. By compressing data, the computing device may reduce the amount of data that is transmitted over a network and/or the amount of memory or storage required to store the data. That is, a fast and effective data compression technique may reduce the bandwidth consumption and storage requirements of the computing device.

Dictionary coding is a broad category of data compression techniques and technologies that operate by using a dictionary (e.g., a table of data patterns) to identify sequences or patterns in the data to be compressed and replacing identified patterns with a reference (e.g., a symbol, code or address) to the corresponding entry in the dictionary. By replacing repeated patterns with shorter references, dictionary coding techniques can significantly reduce the size of the data.

Lempel-Ziv (LZ) compression techniques are similar to dictionary coder techniques but do not start with a predefined dictionary. Rather, LZ compression techniques are adaptive, dynamically building the dictionary based on the actual compression data as the data is being encoded. The dictionary is frequently updated to include recently processed input data, thus growing the list of previously seen phrases. Due to these and other characteristics, LZ compression techniques have become popular and widely used in processing systems in which performance, storage, power consumption, and/or bandwidth consumption characteristics are important.

### SUMMARY

Various aspects include methods of performing enhanced coding operations, which may include receiving an input data stream, querying a search table with sequences of bytes, characters, or symbols in the received input data stream to receive one or more location vectors for each byte, character, or symbol, querying a match table with the received location vectors to identify the starts and ends of matching sequences, performing a history buffer check in response to determining that a match failed in the match table to determine whether the match failure or miss may be valid, determining copy and literal commands for the input data stream based on heuristics and the results of the queries to the search table, the match table, or the history buffer, and performing enhanced Huffman coding operations to encode the copy and literal commands into a compressed bitstream, using shorter codes for frequently occurring patterns and longer codes for less frequently occurring patterns.

In some aspects, performing the history buffer check in response to determining that the match failed in the match table to determine whether the match failure or miss may be valid may include determining a current position in the match table being checked for repeated sequences, and performing the history buffer check based on whether the current position in the match table may be less than a last index of the search table.

In some aspects, performing the history buffer in response to determining that the match failed in the match table to determine whether the match failure or miss may be valid may include determining a current position in the match table being checked for repeated sequences, determining whether the current position may be within a range that was already covered by the search table, and forgoing performing the history buffer check in response to determining that the current position in the match table may be less than a value of a last index of the search table.

In some aspects, performing the history buffer check in response to determining that the match failed in the match table to determine whether the match failure or miss may be valid may include determining a current position in the match table being checked for repeated sequences, determining whether the current position may be less than a value of the search table[last index], determining whether a search table valid flag[last index] may be set, and performing the history buffer check in response to determining that a position in the match table may be less than the value of search table[last index] and that the search table valid flag[last index] has been set.

In some aspects, the search table stores a static vector for each sequence that represent historical locations in which the sequence has previously been encountered in the input data stream, the search table implements a rolling window of history in which oldest location in the static vector may be removed when the vector may be full and a new occurrence of sequence may be encountered, and performing the history buffer check in response to determining that the match failed in the match table to determine whether the match failure or miss may be valid may include determining a current position in the match table being checked for repeated sequences, determining whether the static vector in the search table for a sequence character has been filled, determining that every instance of that character in the input data stream up until the current position may be recorded in the search table in response to determining that the static vector in the search table for sequence has not been filled, and forgoing performing the history buffer check in response to determining that every instance of that character in the input data stream up until the current position may be recorded in the search table.

In some aspects, performing the history buffer check in response to determining that the match failed in the match table to determine whether the match failure or miss may be valid may include using a heuristic to speculatively access the history buffer in parallel with the match table query to preemptively fetch data and reduce potential delays that are due to an order in which instructions are executed by hardware.

In some aspects, using the heuristic to speculatively access the history buffer in parallel with the match table query to preemptively fetch the data and reduce potential delays that are due to the order in which instructions are executed by hardware may include prioritizing checking oldest matches first, and prioritizing checking newest matches in response to determining that the match table query failed to identify the match.

In some aspects, querying the match table with the received location vectors to identify starts and ends of matching sequences may include querying the match table to identify sequences in the input data stream that match previously identified sequences based on locations indexed in the search table, and performing the history buffer check in response to determining that the match failed in the match table to determine whether the match failure or miss may be valid may include searching portions of the history buffer that correspond to indexes that were miss by the search table for each location that does not match a previously identified sequence in the match table to verify that the match was not missed in the search table.

Some aspects may further include improving the efficiency of hardware decoding operations by generating enhanced Huffman tables that constrain Huffman codes to only sequences that include a series of all zeros or a series of zeros followed by a single one.

Some aspects may further include using a most recently used (MRU) table to keep track of recently used literals and using a special code to index into the MRU table to reduce the size of each literal by two bits.

Some aspects may further include using a most recently used (MRU) table to keep track of recently used copy distances in copy commands and accessing frequently used copy distances from the MRU table.

Further aspects may include a computing device having a processor configured with processor-executable instructions to perform various operations corresponding to the methods discussed above.

Further aspects may include a computing device having various means for performing functions corresponding to the method operations discussed above.

Further aspects may include a non-transitory processor-readable storage medium having stored thereon processor-executable instructions configured to cause a processor to perform various operations corresponding to the method operations discussed above.

### BRIEF DESCRIPTION OF THE DRAWINGS

The accompanying drawings, which are incorporated herein and constitute part of this specification, illustrate exemplary embodiments of the claims, and together with the general description given above and the detailed description given below, serve to explain the features of the claims.

FIG. 1 is a system block diagram of processing system in the form of a system in a package (SIP) that is suitable for implementing the various embodiments.

FIG. 2 is a component block diagram illustrating components in a computing device that could be configured to perform compression and/or decompression operations in accordance with the various embodiments.

FIGS. 3A and 3B are component block diagrams illustrating components and operations in a computing device that could be configured to perform compression and/or decompression operations in accordance with the various embodiments.

FIGS. 4A-4D are component block diagrams illustrating example codeword table information structures that could be included and used by a computing device to perform compression and/or decompression operations in accordance with some embodiments.

FIGS. 5-7 are block diagrams illustrating components and interactions in encoder devices suitable for performing enhanced compression operations in accordance with some embodiments.

FIGS. 8 and 9 are block diagrams illustrating components and interactions in decoder devices suitable for performing enhanced decompression operations in accordance with some embodiments.

FIG. 10 is a block diagram illustrating components for implementing page compression hardware integration v in a computing device that may be configured to perform compression and/or decompression operations in accordance with some embodiments.

FIG. 11 is a block diagram illustrating an example of page compression software and/or hardware architecture of a computing device that may be configured to perform compression and/or decompression operations in accordance with some embodiments.

FIG. 12 is a process flow diagram illustrating a method of performing enhanced coding operations in accordance with some embodiments.

FIG. 13 is a block diagram illustrating an example processing system in the form of a service computing device that may be used to implement some embodiments.

### DETAILED DESCRIPTION

The various embodiments will be described in detail with reference to the accompanying drawings. Wherever possible, the same reference numbers will be used throughout the drawings to refer to the same or like parts. References made to particular examples and implementations are for illustrative purposes and are not intended to limit the scope of the claims.

In overview, various embodiments include methods, and computing devices configured to implement the methods, for performing enhanced coding operations (e.g., compression, decompression, LZ-based compression techniques, etc.). A computing device may include a processing system configured to receive an input data stream, query a search table with sequences of bytes, characters, or symbols in the received input data stream to receive one or more location vectors for each byte, character, or symbol, query a match table with the received location vectors to identify the starts and ends of matching sequences, and perform a history buffer check in response to determining that a match failed in the match table to determine whether the match failure or miss may be valid. The computing device processing system may determine copy and literal commands for the input data stream based on heuristics and the results of the queries to the search table, the match table, or the history buffer. The computing device processing system may perform enhanced Huffman coding operations to encode the copy and literal commands into a compressed bitstream, using shorter codes for frequently occurring patterns and longer codes for less frequently occurring patterns.

A number of different types of memories and memory technologies are available or contemplated in the future, any or all of which may be included and used in systems and computing devices that implement the various embodiments. Such memory technologies/types may include non-volatile random-access memories (NVRAM) such as Magnetoresistive RAM (M-RAM), resistive random access memory (ReRAM or RRAM), phase-change random-access memory (PC-RAM, PRAM or PCM), ferroelectric RAM (F-RAM), spin-transfer torque magnetoresistive random-access memory (STT-MRAM), and three-dimensional cross point (3D-XPOINT) memory. Such memory technologies/types may also include non-volatile or read-only memory (ROM) technologies, such as programmable read-only memory (PROM), field programmable read-only memory (FPROM), one-time programmable non-volatile memory (OTP NVM). Such memory technologies/types may further include volatile random-access memory (RAM) technologies, such as dynamic random-access memory (DRAM), double data rate (DDR) synchronous dynamic random-access memory (DDR SDRAM), static random-access memory (SRAM), and pseudostatic random-access memory (PSRAM). Systems and computing devices that implement the various embodiments may also include or use electronic (solid-state) non-volatile computer storage mediums, such as FLASH memory. Each of the above-mentioned memory technologies include, for example, elements suitable for storing instructions, programs, control signals, and/or data for use in or by a vehicle's advanced driver assistance system (ADAS), system on chip (SOC) or other electronic component. Any references to terminology and/or technical details related to an individual type of memory, interface, standard or memory technology are for illustrative purposes only, and not intended to limit the scope of the claims to a particular memory system or technology unless specifically recited in the claim language.

The term “ZRAM” may be used herein to refer to a kernel feature that enables the creation of a compressed block device in RAM. ZRAM is often used on devices with limited physical memory, such as embedded systems, smartphones, and low-end hardware, where the performance benefits of using compressed RAM may be particularly important. ZRAM essentially provides a form of virtual swap space that uses compression to store data in memory. ZRAM may improve system performance by reducing the amount of data that needs to be written to or read from slower disk-based swap space. Instead of swapping out memory pages to disk, ZRAM may compress the data and store it in a compressed block device within RAM. This allows for faster read and write operations, as accessing data from RAM is significantly faster than accessing it from a hard disk. As such, the compression techniques used for the ZRAM may be particularly important since they may have a significant impact on the amount of data that may be stored in the limited amount of available RAM. When memory pressure increases and the system needs to reclaim memory, ZRAM may quickly decompress the compressed data and release the original uncompressed pages back into memory.

Lempel-Ziv (LZ) based compression techniques are widely used in modern computing devices due to their ability to reduce data sizes by identifying repetitions within the data and encoding the repetitions as references to a previous occurrence of that repetition. For example, an LZ component may operate by scanning the data to identify repetitions or repeated sequences of data. In response to identifying a repetition or repeated sequence of data, the LZ component may store a reference to an earlier instance of the data (i.e., instead of storing the actual data).

The Lempel-Ziv (LZ) technique refers do patterns of data as “literals,” which is used herein to refer to a unit of information that represents a unique sequence of data in an input data stream that has not been replaced with references to an earlier occurrence. Literals are typically individual characters or bytes of data that have not been previously encountered in the data stream or which cannot be efficiently represented by a reference to an earlier occurrence.

The Lempel-Ziv (LZ) technique refers to “copy commands,” which is used herein to refer to a type of compression operation that provides instructions to replicate or “copy” a sequence of data that has been previously encountered in the data stream. The Lempel-Ziv (LZ) technique refers to “command distance,” which is used herein to refer to a location of a repeated data sequence in memory. For example, copy commands may include a command distance value that indicates how far back in memory the processing system should look in order to find a sequence to be copied. Specifying the distance in the copy command may allow the computing device to find and replicate a desired data sequence more quickly and/or more efficiently.

LZ-based compression techniques typically use two type of instructions: copy commands and literal commands. A copy command may indicate that a certain sequence of data has been seen before and tells the decompressor to copy a certain length of data from a certain position in the already-decompressed data. A literal command may be used for data that has not been seen recently to tell the decompressor to add a certain piece of data directly to the output. For example, if the phrase “data compression,” is repeated multiple times in a text, the character sequence “data compression” would be a literal the first time it is encountered. The next time it is encountered, the LZ component may use a copy command to instruct the system to replicate the phrase from its first occurrence (i.e., instead of storing it each time it appears). When there are many repetitions in the data, storing references to each repeated sequence (as opposed to the actual sequence) may significantly reduce the size of the data that is stored or transmitted.

A common technical challenge in using LZ-based compression techniques is determining which parts of the data to represent as copy commands and which to represent as literals. This often requires balancing tradeoffs between reducing the size of the compressed data and performing computationally intensive tasks that could have a significant negative impact on the responsiveness, performance and/or power consumption characteristics of a computing device.

While conventional LZ compression techniques are generally effective, they may include various inefficiencies that could slow down the overall compression process and/or consume an excessive amount of the processing, memory, and/or battery resources in the computing device. For example, conventional LZ techniques may require frequent memory sequence checks or searches within the data being compressed to identify new data sequences. Since many of these checks or searches do not identify new sequences, the computing device often performs a large number of extraneous, unsuccessful, or unnecessary memory operations that slow the compression process or consume an excessive amount of the computing device's often limited resources. As another example, conventional LZ techniques update the dictionary as new patterns or sequences are identified. If the data includes many patterns or sequences, the dictionary may become exceedingly large. Searching through such a large dictionary may further slow down the overall compression process and/or consume an excessive amount of the computing device's processing and/or battery resources.

Various embodiments may include a computing device that is equipped with an enhanced coder component configured to implement an enhanced compression/decompression technique that overcomes at least some of the above-described limitations of conventional solutions (e.g., conventional LZ-based compression techniques, etc.).

In various embodiments, the enhanced coder component may be configured to perform enhanced LZ compression operations that reduce, minimize, or eliminate unnecessary checks and searches and/or otherwise improves the efficiency of the compression operations. As a result, the enhanced coder component may improve the performance, functionality, throughput, and/or power consumption characteristics of the computing device. For these and other reasons, various embodiments are particularly useful for critical software applications and/or applications for which data compression is important, such as in ZRAM, firmware compression, or for suspend-to-RAM operations.

In some embodiments, the enhanced coder component may be configured to use heuristic rules, an entropy coder, advanced data structures (e.g., to implement a search table, match table, history buffer, etc.), most recently used (MRU) optimizations, Huffman coding tables, and/or specialized hardware configurations to reduce, minimize, or eliminate unnecessary checks and searches and/or to otherwise improve the efficiency of the data compression operations.

In some embodiments, the computing device may be equipped with a search table, a match table, and a history buffer. The computing device may use the search table to log the locations of each symbol encountered in the data stream and map each character to a specific column. The computing device may use the match table to store information about ranges of symbols that match previous sequences and/or to determine whether an identified match may be extended or should be ended. The computing device may use the history buffer to maintain a record of all processed symbol locations and/or to provide a comprehensive determination of whether a match fails in the match table.

In some embodiments, the enhanced coder component may be configured to commence receiving and processing an input data stream for compression, map each character in the input data stream to a specific column in the search table, log the location of each mapped character, query the match table for a matching previous sequence, determine whether identified matches may be extended, and query the history buffer for missed matches.

In some embodiments, the enhanced coder component may be configured to use heuristic rules to circumvent certain operations if specific conditions are met. For example, the enhanced coder component may be configured to use heuristic rules that streamline history buffer access operations and reduce unnecessary checks in the history buffer, thereby improving the performance and power consumption characteristics of the device.

In some embodiments, the enhanced coder component may be configured to use a first rule that limits history buffer checks/accesses to instances in which the current position in the match table is less than the last index of the search table to reduce or eliminate unsuccessful or unnecessary history buffer access operations. For example, the enhanced coder component may apply a heuristic rule to determine whether the current position in the match table is less than the last index of the search table and forgo querying the history buffer for missed matches in response to determining that the current position in the match table is less than the last index of the search table.

In some embodiments, the enhanced coder component may be configured to use a second rule to avoid history buffer checks/accesses in response to determining that a vector in the search table is not fully populated, which may indicate insufficient encounters with a specific symbol for any location to fall on the search table. For example, the enhanced coder component may apply a heuristic rule to determine whether an entire vector within the search table is filled and forgo querying the history buffer for missed matches in response to determining that the entire vector within the search table is not filled.

In some embodiments, the enhanced coder component may be configured to use speculative access techniques to improve history buffer lookups that occur in parallel to match operations. For example, the enhanced coder component may be configured to speculatively query the history buffer prior to determining that the match table does not include a matching previous sequence. In some embodiments, the enhanced coder component may be configured to prioritize older matches for the speculative queries.

As mentioned above, compression techniques may perform various operations to determine which parts of the data to represent as copy commands and which to represent as literals. After the literals and copy commands are determined, these data items need to be stored in a way that can be readily accessed and read by a decompressor. Different compression algorithms use different methods of encoding to store the determined literals and copy commands so that the literals and copy commands can be readily accessed and read by a decompressor. Entropy coding is one such method used in lossless data compression that assigns shorter codes to frequently occurring patterns (or symbols) and longer codes to less frequent ones. Huffman coding is a popular entropy coding technique.

In some embodiments, the computing device and/or enhanced coder component may be equipped with an entropy coder that is configured to implement an enhanced Huffman coding technique. For example, the entropy coder may be configured to use a static Huffman table with codes that include zeros followed by a single one or codes that include all zeros. For example, the entropy coder may be configured to convert the received input data into Huffman codes and generate a static Huffman table that includes codes that include a sequence of zeros or a sequence of zeros followed by a single one. This may allow the entropy coder to accelerate the hardware decoding operations because the decoder only needs to count the number of zeros preceding the one. In some embodiments, the enhanced coder component may mark entries in the table that include all zeros as a special case.

In some embodiments, the computing device may divide copy commands into orthogonal command types and match the bit widths to probabilities to enhance compression efficiency. In some embodiments, the enhanced coder component may be configured to perform most recently used (MRU) operations that include maintaining an MRU table of the most recently used literals (or command distances). Rather than outputting a literal or command distance, the enhanced coder component may index a unique code into the MRU table, thereby saving two bits per literal, etc.

In some embodiments, the enhanced coder component may be configured to perform enhanced Huffman encoding operations that include performing parsing operations for the copy commands and/or MRU operations for the literals and copy command distances.

The parsing operations may include parsing the copy commands into orthogonal command types and matching the bit widths to probabilities to enhance their compression efficiencies. Orthogonal commands may be commands that are independent of each other so that a change in one command does not directly impact another command. This independence may allow each command to be processed more efficiently and/or may simplify the design and implementation of the compression algorithm.

The MRU operations may include prioritizing access to the most recently processed data items to exploit the principles of data recency or temporal locality, which postulates that items accessed recently are likely to be accessed again in the near future. By prioritizing access to the most recently processed data items, the MRU operations may speed up the retrieval and processing of literals and copy command distances, and in turn, improve the performance and efficiency of the Huffman encoding process.

In some embodiments, the enhanced coder component may be configured to use the Huffman coding tables to perform Huffman decoding operations. For example, the enhanced coder component may receive encoded data that includes a series of symbols in which each symbol is represented by a specific Huffman code obtained from a set of Huffman coding tables, the Huffman code for each data element is represented by a sequence of zeros preceding a one, and the Huffman code for an MRU element includes a prefix and two bits. The enhanced coder component may decode each symbol by counting the number of zeros in the Huffman code preceding a one to determine the original data element, identify an MRU Huffman code by identifying the specific prefix and two bits, and use the identified MRU Huffman code to identify one of the four most recently used elements to substitute in place of a literal or a copy distance. In some embodiments, the enhanced coder component may use Huffman coding tables and/or MRU techniques to circumvent known hardware decoding constraints.

In some embodiments, the computing device may be equipped with hardware-based tables that are configured to support the processing of multiple codes within a single cycle. In some embodiments, the enhanced coder component may be configured to perform code packetization operations to strategically reduce the search space for determining the values. The code packetization operations may include receiving encoded data that includes codes that each include a prefix code and payload data bits, and restructuring or reorganizing the received encoded data into a packetized format or structure in which all prefix codes are placed at the start of the packet and the payload data bits are placed at the end of the packet.

Each prefix code may be exclusive and/or may produce a fixed width. This uniformity may allow the system to quickly skip to the subsequent code without performing any time-consuming or computationally intensive operations. That is, the enhanced coder component may utilize the packetized format/structure (e.g., the identified fixed width of each prefix code, etc.) to identify each code based on the fixed width of the prefix code and promptly skip to the next code for processing. This may in turn allow the computing device to process multiple codes per cycle, which may be a significant advantage when processing large volumes of data.

In some embodiments, the enhanced coder component may use a combination of heuristic rules and efficient data organization and/or data structures to reduce or minimize unnecessary checks. The enhanced coder component may use the heuristic rules to guide its decision-making process during compression, reducing wasted resources on ineffective searches. The enhanced coder component may organize the data to reduce the amount of time and energy required to access or manipulate the data. As such, the enhanced coder component may significantly speed up the compression (coding) and decompression (decoding) operations, thereby improving the efficiency of the processing system.

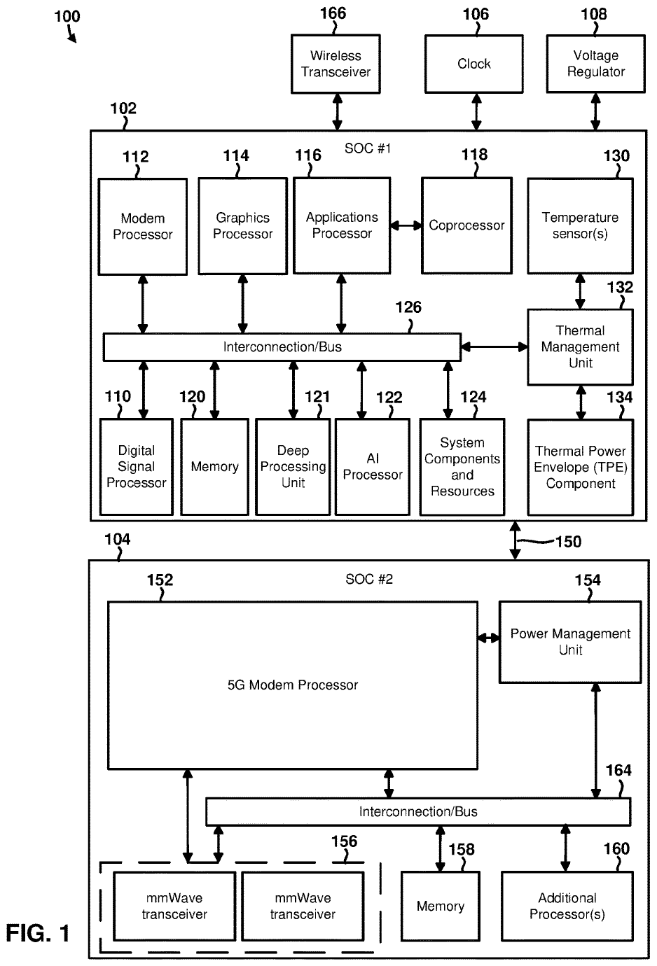

Various embodiments may be implemented on a processing system that may include a number of single-processor and multiprocessor computer systems, including a system-on-chip (SOC) or system in a package (SIP). FIG. 1 illustrates an example processing system or SIP 100 architecture that may be used in mobile computing devices implementing various embodiments.

The example SIP 100 illustrated in FIG. 1 includes two SOCs 102, 104, a clock 106, a voltage regulator 108, and a wireless transceiver 166. The first and second SOC 102, 104 may communicate via interconnection/bus module 150. The various processors 110, 112, 114, 116, 118, 121, 122, may be interconnected to each other and to one or more memory elements 120, system components and resources 124 and a thermal management unit 132 via an interconnection/bus module 126. Similarly, the processor 152 may be interconnected to the power management unit 154, the mm Wave transceivers 156, memory 158, and various additional processors 160 via the interconnection/bus module 164. The interconnection/bus module 126, 150, 164 may include an array of reconfigurable logic gates and/or implement a bus architecture (e.g., CoreConnect, AMBA, etc.). Communications may be provided by advanced interconnects, such as high-performance networks-on-chip (NoCs).

In some embodiments, the first SOC 102 may operate as the central processing unit (CPU) of the mobile computing device that carries out the instructions of software application programs by performing the arithmetic, logical, control and input/output (I/O) operations specified by the instructions. In some embodiments, the second SOC 104 may operate as a specialized processing unit. For example, the second SOC 104 may operate as a specialized 5G processing unit responsible for managing high volume, high speed (e.g., 5 Gbps, etc.), and/or very high-frequency short wavelength (e.g., 28 GHz mm Wave spectrum, etc.) communications.

The first SOC 102 may include a digital signal processor (DSP) 110, a modem processor 112, a graphics processor 114, an application processor 116, one or more coprocessors 118 (e.g., vector co-processor) connected to one or more of the processors, memory 120, deep processing unit (DPU) 121, artificial intelligence processor 122, system components and resources 124, an interconnection/bus module 126, one or more temperature sensors 130, a thermal management unit 132, and a thermal power envelope (TPE) component 134. The second SOC 104 may include a 5G modem processor 152, a power management unit 154, an interconnection/bus module 164, a plurality of mm Wave transceivers 156, memory 158, and various additional processors 160, such as an applications processor, packet processor, etc.

Each processor 110, 112, 114, 116, 118, 121, 122, 121, 122, 152, 160 may include one or more cores, and each processor/core may perform operations independent of the other processors/cores. For example, the first SOC 102 may include a processor that executes a first type of operating system (e.g., FreeBSD, LINUX, OS X, etc.) and a processor that executes a second type of operating system (e.g., MICROSOFT WINDOWS 10). In addition, any or all of the processors 110, 112, 114, 116, 118, 121, 122, 152, 160 may be included as part of a processor cluster architecture (e.g., a synchronous processor cluster architecture, an asynchronous or heterogeneous processor cluster architecture, etc.).

Any or all of the processors 110, 112, 114, 116, 118, 121, 122, 152, 160 may operate as the CPU of the mobile computing device. In addition, any or all of the processors 110, 112, 114, 116, 118, 121, 122, 152, 160 may be included as one or more nodes in one or more CPU clusters. A CPU cluster may be a group of interconnected nodes (e.g., processing cores, processors, SOCs, SIPs, computing devices, etc.) configured to work in a coordinated manner to perform a computing task. Each node may run its own operating system and contain its own CPU, memory, and storage. A task that is assigned to the CPU cluster may be divided into smaller tasks that are distributed across the individual nodes for processing. The nodes may work together to complete the task, with each node handling a portion of the computation. The results of each node's computation may be combined to produce a final result. CPU clusters are especially useful for tasks that can be parallelized and executed simultaneously. This allows CPU clusters to complete tasks much faster than a single, high-performance computer. Additionally, because CPU clusters are made up of multiple nodes, they are often more reliable and less prone to failure than a single high-performance component.

The first and second SOC 102, 104 may include various system components, resources, and custom circuitry for managing sensor data, analog-to-digital conversions, wireless data transmissions, and for performing other specialized operations, such as decoding data packets and processing encoded audio and video signals for rendering in a web browser. For example, the system components and resources 124 of the first SOC 102 may include power amplifiers, voltage regulators, oscillators, phase-locked loops, peripheral bridges, data controllers, memory controllers, system controllers, Access ports, timers, and other similar components used to support the processors and software clients running on a mobile computing device. The system components and resources 124 may also include circuitry to interface with peripheral devices, such as cameras, electronic displays, wireless communication devices, external memory chips, etc.

The first and/or second SOCs 102, 104 may further include an input/output module (not illustrated) for communicating with resources external to the SOC, such as a clock 106, a voltage regulator 108, and a wireless transceiver 166 (e.g., cellular wireless transceiver, Bluetooth transceiver, etc.). Resources external to the SOC (e.g., clock 106, voltage regulator 108, wireless transceiver 166) may be shared by two or more of the internal SOC processors/cores.

In addition to the example SIP 100 discussed above, various embodiments may be implemented in a wide variety of processing systems, which may include a single processor, multiple processors, multicore processors, or any combination thereof.

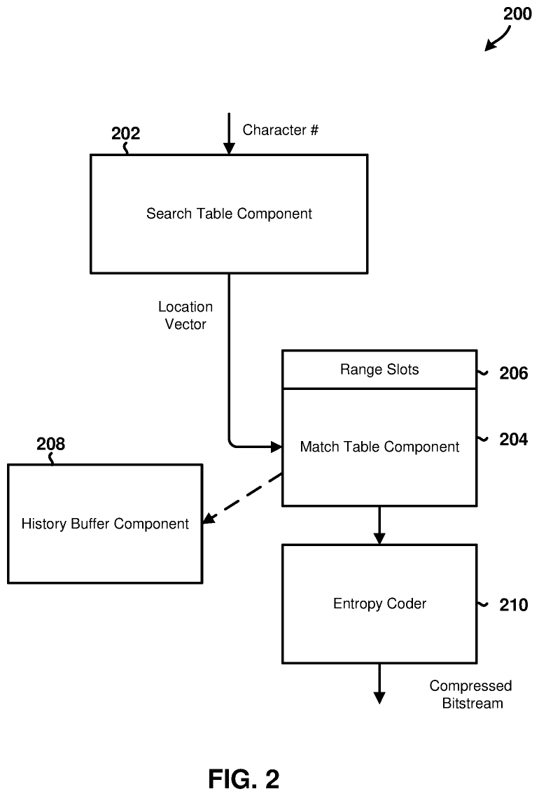

FIG. 2 illustrates example components in a processing system 200 that could be configured in accordance with some embodiments. With reference to FIGS. 1 and 2, a processing system 200 or subsystem (e.g., SIP 100, SOC 102, 104, etc.) may include a search table 202 component, a match table 204 component that includes range slots 206, a history buffer 208 component, and an entropy coder 210.

The processing system 200 may include an enhanced coder component that is configured to receive an input data stream. The input data stream may be the original uncompressed data that is to be compressed. The enhanced coder component may commence analyzing the input data stream for compression and query the search table 202 with sequences of bytes or characters in the received input data stream. The enhanced coder component may use the search table 202 queries to identify repeated sequences in the data.

The search table 202 may receive as input a sequence of bytes or characters and generate as output a vector of locations for each byte or character. The search table 202 may index the data by character locations, effectively storing where each byte was last seen in the data. By indexing the data based on character locations, the search table 202 may reduce the need to search an entire history buffer 208 or the entire history of the data to identify patterns. This may in turn improve the speed and efficiency of the compression operations.

In some embodiments, the enhanced coder component may query the search table 202 with sequences of bytes or characters in the received input data stream to receive one or more location vectors or vectors of locations for each byte, character, or symbol. The enhanced coder component may query the match table 204 with the received location vectors.

The match table 204 may be configured to receive and use the vector of locations to identify ranges of locations in which data sequences (bytes) appear multiple times. The match table 204 may categorize identified sequences that match a previous sequence as a “match range,” and store these match ranges in range slots 206. The enhanced coder component may be configured to query the match table 204 repeatedly to identify the starts and ends of matching sequences until no more matches are found. As part of these operations, the enhanced coder component and/or match table 204 may determine whether a new byte position extends a known match range, determine that a larger repeat sequence has been found in response to determining that a new byte position extends the known match range, and store updated match ranges in range slots 206 to represent the newly identified repeat sequence. The enhanced coder component and/or match table 204 may perform these operations repeatedly or continuously to identify the longest matching sequences possible until no more matches are found.

The history buffer 208 may be configured to store and maintain a comprehensive history of the data processed and/or to serve as a backup to the search table 202 and match table 204. When a potential match fails in the match table 204, the enhanced coder component may query the history buffer 208 to determine whether the match failure in match table 204 is indeed a failure or whether there is a match that was overlooked by the search table 202. As such, the history buffer 208 may prevent the matching operations from terminating prematurely and/or to further support and maintain the accuracy and effectiveness of the compression operations.

As mentioned above, the copy and literal commands are instructions that the compression algorithm uses to represent the data. Copy commands indicate that a certain sequence of data has been seen before, while literal commands represent data that has not been seen recently. In some embodiments, the enhanced coder component may be configured to determine the copy and literal commands based on heuristics. In some embodiments, the enhanced coder component may be configured to determine the copy and literal commands to balance tradeoff between the efficiency and effectiveness of compression operations.

The entropy coder 210 may be configured to receive the identified copy commands and literal commands and perform enhanced Huffman coding operations to encode the commands into a compressed bitstream. The entropy coder 210 may use shorter codes for frequently occurring patterns and longer codes for less frequent ones, thereby reducing the number of bits used for the compressed bitstream output.

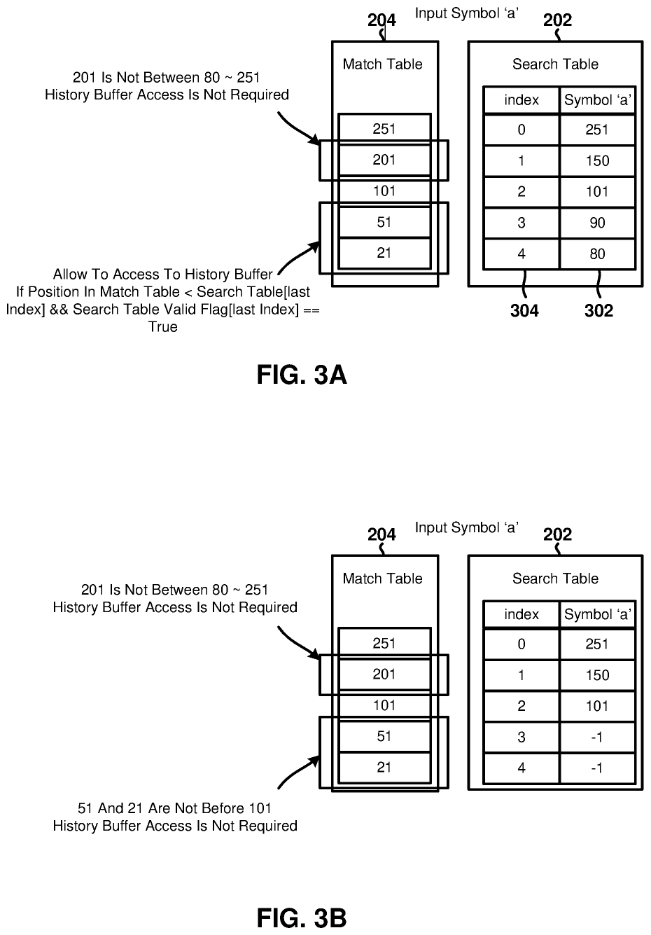

FIGS. 3A and 3B illustrate example components in a processing system that could be configured in accordance with some embodiments. With reference to FIGS. 1-3B, in the illustrated examples, the processing system operates on a 256-character set. As such, it should be understood that the illustrated search table 202 and match table 204 each represent a single column of a larger 256-column table that includes a column for each character. For ease of reference, the examples below discuss the operations with reference to the single column for symbol or character ‘a.’

In the example illustrated in FIG. 3A, the processing system includes a match table 204 that represents the positions of character ‘a’ in the input data stream and a search table 202 that represents the last known positions for character ‘a’, sorted from the most recent to the earliest. The search table 202 indicates that the earliest known position is 80. As a result, the enhanced coder component may determine with a high degree of confidence that the search table 202 includes a comprehensive or exhaustive list of the positions/locations for the character ‘a’ from position 80 onwards (e.g., to 251).

The match table 204 includes a position 201 that is not between 80 and 251 in the search table 202, which may indicate that location 201 was a miss in the search table 202. Since the enhanced coder component previously determined that the search table 202 includes comprehensive records for positions 80 to 251, the enhanced coder component may determine that there is a high probability that the miss was valid and/or that the position 201 will also fail to match in the history buffer 208.

The match table 204 also includes locations 21 and 51. Since these are older than the earliest known position (80) in the search table 202, the enhanced coder component cannot readily determine whether the miss was a valid miss. That is, locations 21 and 51 may be valid positions for the character ‘a’ that are not recorded in the search table 202. Accordingly, the enhanced coder component may query the history buffer 208 for positions 21 and 51 to ensure that a potentially valid match is not missed.

In some embodiments, the enhanced coder component may be configured to perform data compression operations that may include performing a history buffer check based on whether the current position in the match table 204 is less than the last index of the search table 202. For example, the enhanced coder component may be configured to determine that it is currently operating within a range that was already covered by the search table 202 and forgo performing a history buffer check in response to determining that the current position in the match table 204 is less than the value 302 of the last index 304 of the search table 202. That is, as mentioned above, the search table 202 may store the last seen locations of specific characters in the data stream. As such, the value 302 of the last index 304 of the search table 202 may indicate the latest known position in which a particular character or symbol (e.g., ‘a’) was encountered.

The current position of the match table 204 may indicate the position being checked for repeated sequences (matches) within the data. Since the search table 202 may include a robust or comprehensive list of the last locations of each character/symbol up to its last known location, the enhanced coder component may determine that there is a high probability that any potential matches within this range would have already been identified by search table 202. As a result, the enhanced coder component may forgo performing a history buffer check in response to determining that the value of the current position in the match table 204 is less than the value of the last index of the search table 202.

FIG. 3A illustrates that if a match fails in the search table 202 and the current position in the match table 204 is 201, the enhanced coder component may determine whether the value of the current position (i.e., 201) falls within the range of values between the first and last indexes (i.e., between 251 and 80). Since, in the illustrated example, the value “201” does not fall between the values “80” and “251” (i.e., between the values of the first and last indexes in the search table 202), the enhanced coder component may determine that there are no suitable matches because any potential matches for 201 would have been identified by search table 202 and that the performance of a history buffer check would be an extraneous, unsuccessful, or unnecessary memory operation that could slow the compression process and/or consume an excessive amount of the computing device's often limited resources.

On the other hand, if a match fails in the search table 202 and the current position value in the match table 204 (51 or 21 in the illustrated example) does not fall within the range of values between the first and last indexes (e.g., between 251 and 80 in the illustrated example), the enhanced coder component may determine that a history buffer check could potentially identify a match. In response, the enhanced coder component may determine whether the position in the match table 204 is less than the value of the search table[last index] and whether a search table valid flag[last index] is set (e.g., true, on, 1, etc.). The enhanced coder component may perform the history buffer check in response to determining that the position in the match table 204 is less than the value of search table[last index] and that the search table valid flag[last index] has been set.

Thus, the enhanced coder component may forgo performing a history buffer check in response to determining that the current position in the match table 204 is less than the last index of the search table 202. The enhanced coder component may perform the history buffer check when the current match-checking process goes beyond the range of what the search table 202 has already cataloged.

The search table 202 may store a vector for each character or symbol (“a” in FIGS. 3A and 3B), which may represent the historical locations where the character/symbol has been encountered in the data stream. Due to memory constraints, the size of this vector may be static, finite, or limited. When the vector is full, and a new occurrence of the character is found, the oldest location falls off the end of the vector to make room for the new location. This phenomenon is often referred to as a “rolling window” of history. As such, the enhanced coder component may determine that every instance of that character in the data stream up until the current position is recorded in the search table if the vector in the search table for a particular character has not been filled. In other words, none of the locations for that character have yet fallen off the end of the table.

In the example illustrated in FIG. 3B, the vector in the search table 202 has not been filled and the values of indexes 3 and 4 in the search table 20 are set to −1. These vacant spots may indicate that the symbol ‘a’ has only been seen three times. As a result, the enhanced coder component may determine that the record in the search table 202 for that character/symbol is comprehensive and includes every location in which that character/symbol has been identified in the data and/or that any potential matches involving that character/symbol would have already been captured by the search table 202. In response, the enhanced coder component may determine that it is not necessary to perform a history buffer check for these positions. The enhanced coder component may forgo performing the history buffer check to enhances the efficiency of the compression process by avoiding extraneous, unsuccessful, or unnecessary memory operations that could slow the compression process and/or consume an excessive amount of the computing device's processing and/or battery resources.

In the example illustrated in FIG. 3B the value “201” does not fall between the values “80” and “251” (i.e., between the values of the first and last indexes in the search table 202). As a result, the enhanced coder component may determine that there are no suitable matches because any potential matches for 201 would have been identified by search table 202 and/or that the performance of a history buffer check for the current position would be an extraneous, unsuccessful, or unnecessary memory operation that could slow the compression process and/or otherwise have a significant negative impact on the performance and/or power consumption characteristics of the device.

Generally, hardware constraints may limit the ability of the device or enhanced coder component to determine whether a match exists until the next cycle after the match is identified. This may introduce a delay period during which the enhanced coder component may not be able to commence processing the next set of operations until it determines whether the current data matches a previously encountered pattern or sequence. In some embodiments, the enhanced coder component may be configured to perform history buffer checks during the delay period and/or while the enhanced coder component waits for the match result. Such history buffer checks are speculative because result of the match is not yet known, and thus the history buffer checks may not be necessary.

In some embodiments, the enhanced coder component may be configured to use a heuristic to speculatively access the history buffer during the matching process (e.g., in parallel with the match table queries, etc.) to reduce potential delays due to the order in which tasks or instructions are executed by the hardware and/or to otherwise improve the performance and efficiency of the compression operations. The speculative access operations may include anticipating the need for data and preemptively fetching the data before it is requested or required. The speculative access operations may improve the performance and responsiveness of the computing device by reducing or masking the latencies associated with fetching data from memory.

In some embodiments, the heuristic for speculatively accessing the history buffer may cause the enhanced coder component to prioritize checking the oldest matches first. This is because the oldest matches first are most likely to have fallen off the end of the search table due to the limited capacity of the search table and/or the “rolling window” of history. Said another way, if a match is associated with data that is old in terms of its position in the data stream, there is a high probability that the match is no longer in the search table but still included in the history buffer. The enhanced coder component may adjust the priority based on the results of the match. For example, the enhanced coder component may prioritize checking the newest matches in response to determining that a match failed the search table check. Newer matches may produce better compression results because there is a higher probability that they will represent a longer sequence or pattern of data.

In some embodiments, the enhanced coder component may be configured to query the match table to identify sequences in the input data stream that match previously identified sequences based on the locations indexed in the search table, identify the locations that do not match a previously identified sequence, and query the history buffer for each location that does not match a previously identified sequence failed the match table to verify that the match was not missed in the search table. In some embodiments, rather than searching the entire history buffer, the enhanced coder component may focus its search on the indexes that were missing from the search table for a more targeted and efficient access operation.

In some embodiments, the enhanced coder component may be configured to use enhanced or specialized Huffman tables and/or Huffman codes for encoding data. The enhanced Huffman tables/codes may be modified or adapted to improve the efficiency of the hardware decoding operations.

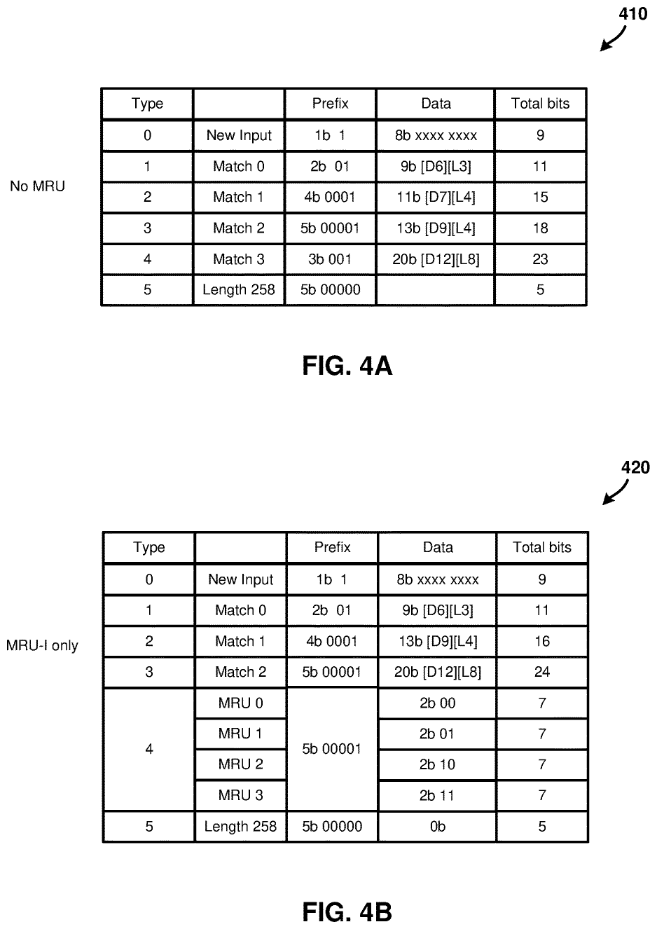

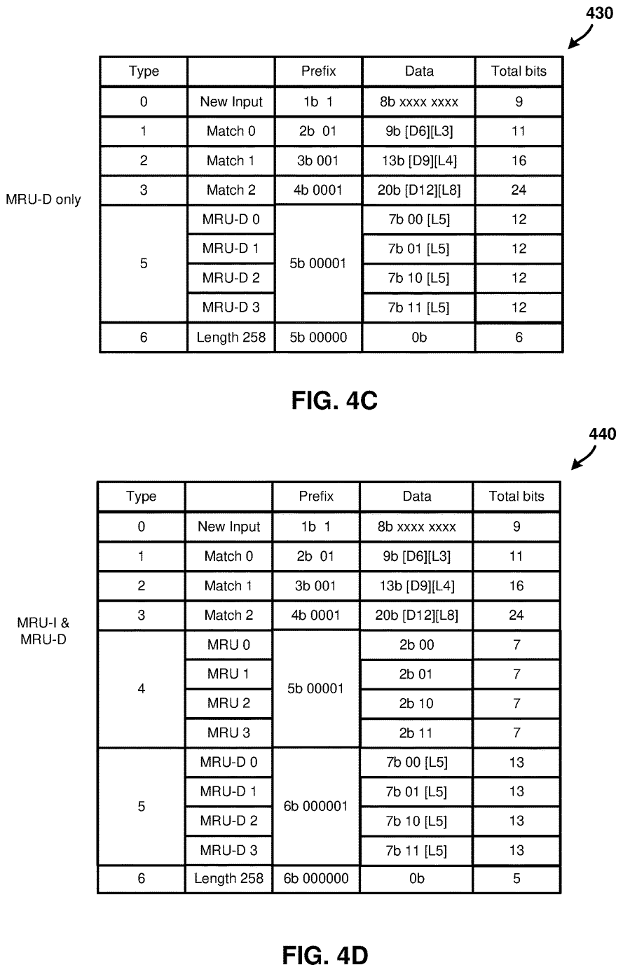

FIGS. 4A-4D illustrate example codeword table information structures 410, 420, 430, 440 that could be used to implement various embodiments. The codeword table 410 illustrated in FIG. 4A provides the coding options without implementing MRU codes. The codeword table 420 illustrated in FIG. 4B provides the coding options and implements most recently used literal (MRU-L) codes. The codeword table 430 illustrated in FIG. 4B provides the coding options and implements most recently used distance (MRU-D) codes. The codeword table 430 illustrated in FIG. 4B provides the coding options and implements both MRU-I and MRU-D codes. The codeword table information structures 410, 420, 430, 440 may all be enhanced Huffman tables that use a narrow code structure to accelerate, expedite and/or simplify the hardware decoding operations.

Generally, conventional Huffman tables adjust bit widths to match symbol probabilities. Unlike conventional Huffman tables, the enhanced Huffman tables use a narrow code structure to accelerate, expedite and/or simplify the hardware decoding operations. For example, in some embodiments, the enhanced Huffman tables may constrain the Huffman codes to only sequences that include a series of all zeros or a series of zeros followed by a single one. Rather than adjusting the bit widths to match symbol probabilities, the enhanced Huffman tables may divide the copy command into several independent orthogonal command types and fine-tune the individual command types may to match the underlying or inherent probabilities of the input data more closely.

With reference to FIGS. 1-4A, each of the codeword tables 410, 420, 430, 440 provide a variety of coding options with or without the implementation of most recently used (MRU) codes. For example, each of the codeword tables 410, 420, 430, 440 include a type column, prefix column, a data column, and a total bits column. The prefix column includes a prefix (e.g., 1b, 2b, 3b, 4b, 5b,) followed by a sequence that either includes all zeros or a series of zeros followed by a single one. The type column includes a value between 1 and 6. Type 0 may be a literal and/or include one bit followed by the literal bits, adding up to a total of 9 bits. Type 1, or match 0 (or a copy command) may include 2 bits (2b) and may be used for commands that have a distance that may be represented in 6 bits (D6) and a length of 3 bits (L3). Other match types may include different bit storages for distance and length. In the illustrated example, the distance and length go up to a distance of 12 bits (D12) and a length of 8 bits (L8). Type 5 may be associated with a special code that represents a length of 258, which may be used to extend the length of the next copy command.

In some embodiments, the enhanced coder component may be configured to use a most recently used (MRU) table to keep track of recently used literals. Rather than directly outputting the literals, the enhanced coder component may use a special code to index into the MRU table. As a result, the embodiments may reduce the size of each literal by two bits.

FIG. 4B illustrates an implementation of MRU-I codes for literals. The code structure in FIG. 4B includes a data column that includes a prefix (2b) followed by two bits. These two bits may take one of four possible binary values: 00, 01, 10, or 11. Each value may correspond to a specific MRU index. Instead of outputting a literal, the code indicates which of the four most recently used literals should be substituted in its place. This MRU mechanism provides a more efficient way to reference recently used literals, reducing the overall data size.

In some embodiments, the enhanced coder component may be configured to use a most recently used (MRU) table to keep track of ‘copy distances’ in copy commands. Rather than directly outputting the bits for a command, the enhanced coder component may access frequently used commands from the MRU table. As a result, the embodiments may reduce the size of each copy command by 3 to 11 bits (depending on the size of the command).

FIG. 4C illustrates an implementation of MRU-D codes (e.g., MRU-D 0 to MRU-D3) for code distances. Similar to the example illustrated and described with reference to FIG. 4B, the data column includes a prefix (7b) followed by two bits. These two bits may take one of four possible binary values: 00, 01, 10, or 11. Each value may correspond to a specific MRU index. Instead of directly outputting the bits for a command, the enhanced coder component may access frequently used commands from the MRU table. As a result, the embodiments may reduce the size of each copy command by 3 to 11 bits (depending on the size of the command).

FIG. 4D illustrates an implementation of both an MRU-I and MRU-D that combines the functionalities of the examples illustrated and described with reference to FIGS. 4B and 4C.

In some embodiments, the enhanced coder component may be configured to further improve processing efficiency by performing packetization operations that group multiple codes per cycle. The packetization operations may include placing all prefix codes at the beginning of a packet and all the associated payload data bits at the end. This arrangement reduces the search space necessary to interpret the data.

It should be noted that there is no delimiter between the prefix and data codes. This is due to the exclusive nature of the prefix which may prevent the values from being confused with any other code. Each code generates a fixed width, allowing for easy identification and navigation to the next code.

As an example, packetizing two code packets may include the enhanced coder component arranging the codes of the two packets sequentially or back-to-back, followed by the two payloads, also back-to-back. This structure may accelerate, expedite and/or simplify the hardware decoding operations while maintaining the consistency and interpretability of the data packets.

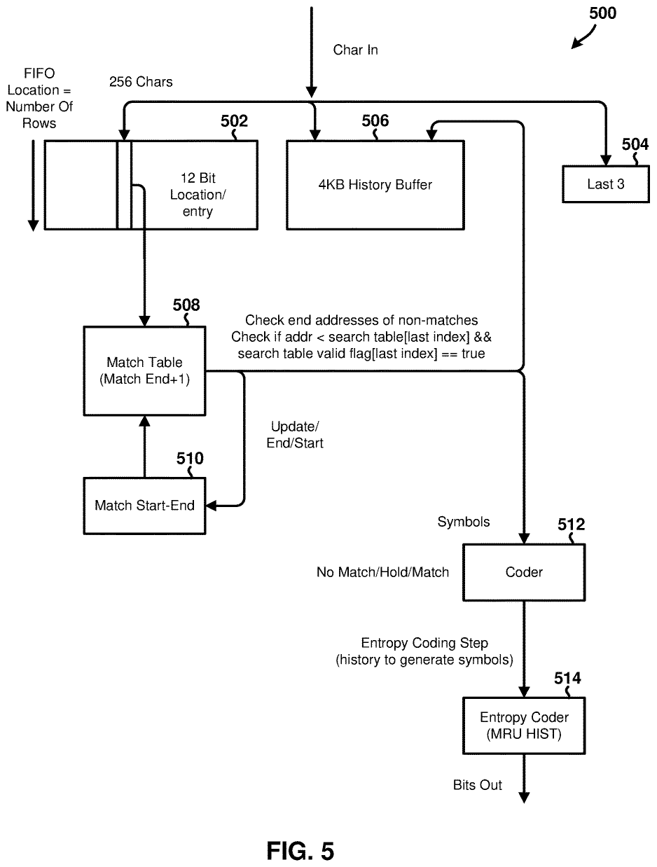

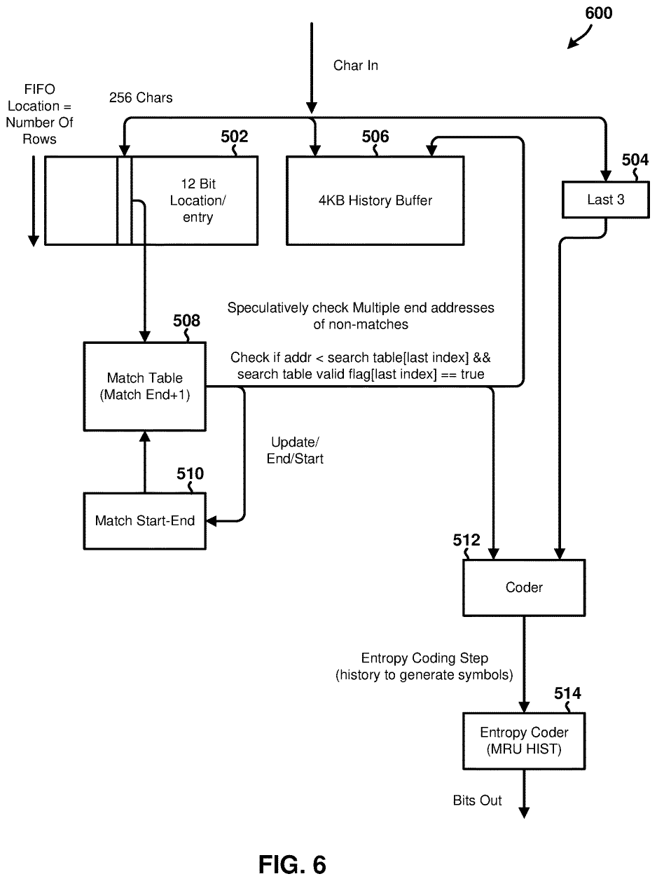

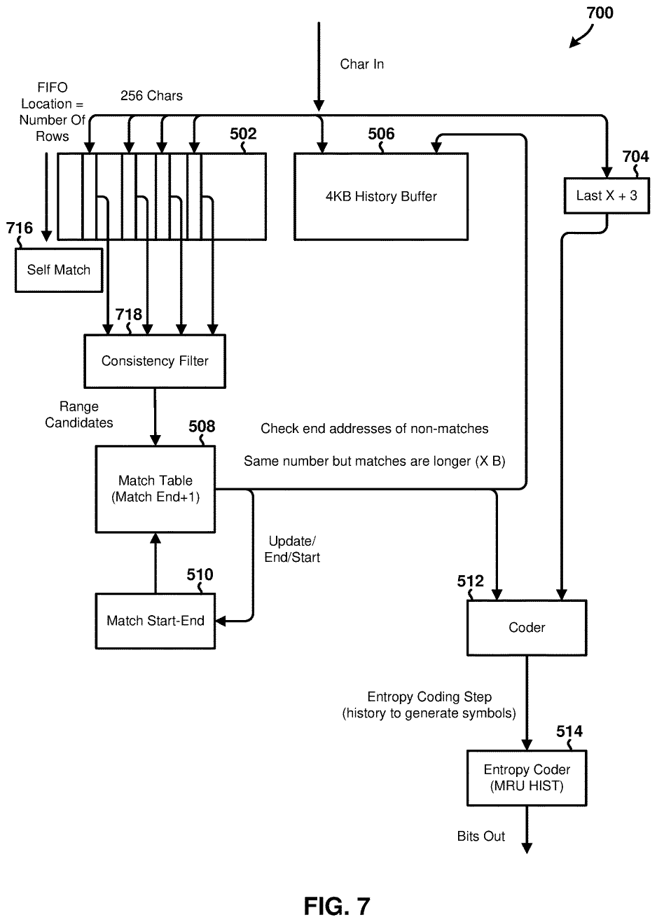

FIGS. 5-7 illustrate example encoder circuits, components or devices that are suitable for performing enhanced compression operations in accordance with various embodiments. In the example illustrated in FIG. 5, the encoder component 500 may be configured to perform enhanced compression operations in accordance with some embodiments. In the example illustrated in FIG. 6, the encoder component 600 is fine-tuned for history buffer access. In some embodiments, the encoder component 600 may be fine-tuned for alternative history buffer access. In the example illustrated in FIG. 7, the encoder component 700 is fine-tuned for multiple bytes per cycle in parallel for the encode operation.

With reference to FIGS. 1-5, the encoder component 500 may include a search table 502, a last 3 504 component, a history buffer 506, a match table 508, a match stat-end 510 component, a coder 512, and an entropy coder 514. The encoder component 500 may be a hardware implementation of the compression operations described above.

The encoder component 500 may receive an access request to the search table 502 in the first cycle. The request may compared to the match table 508 as discussed above, and depending on the match results the history buffer 506 may also be accessed. Symbols may be outputted to the coder 512, which may send the symbols to the entropy coder 514.

This implementation processes 1 byte per cycle, as only 1 byte may be looked up in the search table per cycle and only one set of locations may be matched per cycle. Yet, this throughput may not always be maintained due to potential stalls in the pipeline. The history buffer 506 may only be accessed in the cycle after the match, which may cause stalls. As such, every history buffer check may introduce a stall, which may in turn reduce the processing rate to less than 1 byte per cycle.

The implementation illustrated in FIG. 5 is a straightforward realization of the algorithm of various embodiments, although the implementation may be constrained to 1 byte per cycle due to the search table lookup. In addition, failed matches that require a history buffer check (which may happen one at a time) may lead to pipeline stalls, thus reducing the throughput to less than 1 byte per cycle.

With reference to FIGS. 1-6, FIG. 6 illustrates an implementation in which the encoder component 600 includes a search table 502, a last 3 504 component, a history buffer 506, a match table 508, a match stat-end 510 component, a coder 512, and an entropy coder 514. An incoming character (“Char in”) may be sent to the search table 502 and then to the match table 508. The incoming character also goes into the history buffer 506 and to the ‘last 3’ 504 component. The ‘last 3’ 504 component outputs to the coder 512, which sends its output to the entropy coder 514. The match stat-end 510 communicates with the match table 508, and vice versa. The match table 508 may output to the history buffer 806, and also forward data to the coder 512, which may in turn output data to the entropy coder 514.

The example illustrated in FIG. 6 is a more enhanced encoder component 600 configured to provide more efficient access to the history buffer. The enhanced encoder component 600 may be configured to bank the history buffer to allow multiple accesses to the history buffer in parallel. Generally, “banking” includes dividing the memory or storage into multiple smaller parts (i.e., banks) that may be accessed independently of each other, which may increase the speed and efficiency of memory operations by allowing for parallel or concurrent accesses. As such, the enhanced encoder component 600 may split the history buffer 506 into several smaller independent buffers (i.e., banks) and perform multiple history buffer 506 operations concurrently. This may increase throughput, reduce task completion time, and/or significantly speed up the compression operations.

The enhanced encoder component 600 may simultaneously look up multiple past sequences in the history buffer, substantially speeding up compression operations. In addition, the enhanced encoder component 600 may perform a speculative history buffer check during the match cycle for anticipated missing values. The check may be heuristic-based, favoring older values, which may be more likely to be missing from the search table due to the limited capacity and the “rolling window” characteristics of the history buffer 506. In these embodiments, the enhanced encoder component 600 may only stall when unmatched sequences remain after the speculative history buffer check. In some embodiments, the enhanced encoder component 600 may be configured to use additional heuristics to further reduce stall frequency and increase the overall processing speed.

The enhanced encoder component 600 may be configured to significantly reduce the number of history buffer accesses, which may in turn speed up the compression operations. The enhanced encoder component 600 may decrease the frequency of pipeline stalls and increase the rate at which data is processed. By decreasing pipeline stall frequency and increasing data processing rates, the enhanced encoder component 600 may handle higher throughput, thereby enhancing overall performance and efficiency.

In some embodiments, the enhanced encoder component 600 may be an inline compression engine configured to perform stream encoding or compression operations that include consuming a stream of data and outputting a compressed version of the stream. These operations may be particularly well suited in systems in which the full volume of data is not available at once or the data is too large to fit into memory.

The search table 502 may include a data structure that is configured for quick lookups, such as a hash table, so that when a new character or sequence is received from a data stream character or sequence may be added to the table quickly and made available for matching with future sequences. In some embodiments, the search table 502 may include 12-bit location/entries, which may be a reference or pointer to a specific location in the history buffer. That is, each 12-bit location entry may point to a specific location within this history buffer. As the enhanced encoder component 600 receives the data stream, it may look up previously seen sequences in the history buffer 502 using these 12-bit location entries that each point to a specific location within this history buffer. The enhanced encoder component 600 may access these stored sequences quickly during the matching process to improve the efficiency of the compression operation.

A feature of the system illustrated in FIG. 6 that may increase system performance is the banking of the history buffer 606, which may permit numerous checks to be performed simultaneously. In addition, the encoder speculatively checks the history buffer for likely missing values during the match cycle (using the heuristic of selecting the oldest entries), resulting in a reduced number of history buffer accesses. These operations only stall if missing matches remain after the speculative checks, and up to a maximum defined number of cycles. In some embodiments, the enhanced encoder component 600 in FIG. 6 may be an inline compression engine, processing a stream of data and outputting compressed data. This stream compression may be carried out by checking various buffers and memory locations. Incoming data may be formatted as characters that are added to the search table, with the 12-bit location entries storing the location information for each entry in the history vector, which may facilitate access to the history buffer.

Another feature of the system illustrated in FIG. 6 that may increase system performance is that the enhanced encoder component 600 illustrated in FIG. 6 may operate as a state machine, performing its function without requiring additional processing or programmability. The encoder may process data at high speeds, keep track of characters in the 12-bit location entries, and match characters/sequences to the history buffer. The system may operate at a rate of 1 byte per cycle, with the incoming byte having a location. Processing may be accomplished in 4 KB pages at a time. Each incoming byte may retain its location so that the size of the page becomes irrelevant. The 12-bit entries may be used to convert the incoming character into a list of locations. For example, the 12-bit entries may be used to look up all the past occurrences of that character. This approach is beneficial for improving history buffer access by speculatively accessing the history buffer and filtering the accesses as per the methods discussed above. For these and other reasons, the enhanced encoder component 600 provides significant speed-up in compression operations and reduces the number of history buffer accesses. By doing so, the enhanced encoder component 600 may balance tradeoffs between speed and efficiency in data compression to provide a highly effective solution for high-volume high-throughput data processing environments.

In some embodiments, the enhanced encoder component 600 may be configured to perform an alternative history buffer check to further increase the encoder's throughput. In these embodiments, the enhanced encoder component 600 may be configured to perform data encoding operations that include: creating an initial pool of candidate matches; performing speculative matching operations for candidates that initially fail to match and maintaining the candidates in a speculative state; transitioning to a subsequent cycle; performing a history buffer check for previously unmatched candidates in the subsequent cycle and concurrently initiating the matching process against a new candidate; validating any matches and/or determining whether any of the matches are successful based on whether the candidate passes both the history buffer check from the previous cycle and the current cycle; performing a test to determine whether a failed match is the longest match and is greater than the minimum match in response to detecting a speculative match failure; pruning all current matches to start after the end of a failed match that passes the test and synthesizing a new match from unused candidates of the speculative match; deleting a failed speculative match that does not pass the test and synthesizing a new match from unused candidates of that speculative match; initiating a match with a new unmatched candidate that occupies the extra slot created by the previous candidate's failure when a match becomes speculative due to its candidate failing; imposing restrictions on the number and duration of matches that could be speculative and defining match slots; completing a match to form a copy operation that may be delayed due to late discovery of its end; allowing the matching step to run ahead of the entropy coding step in case the copy operation is delayed due to late discovery of its end; adjusting the ranges of existing matches to start after a match that passes the test and is being admitted; facilitating speculative history buffer checks and maintenance; determining the failure point in response to encountering a match failure and responding accordingly; running the matching step ahead of the entropy coding step to manage potential delays and maintain system throughput; and terminating the decoding operation after all input data has been processed and all matches and literals have been outputted, ensuring all speculative matches have been addressed and no data is left unprocessed.

As mentioned above, in some embodiments, the enhanced encoder component 600 may be configured to perform an alternative history buffer check to further increase the encoder's throughput. In these embodiments, the enhanced encoder component 600 may perform speculative matching operations for candidates that initially fail to match. In the subsequent cycle, these candidates may undergo a history buffer check while concurrently initiating the matching process against a new candidate. During this next cycle, the enhanced encoder component 600 may determine that a match was a successful match if the candidate passes both the history buffer check from the previous cycle and the current candidate match. The enhanced encoder component 600 may determine that the match failed in response to determining that either of these checks failed.

The timing in these embodiments may be different since a history buffer check failure may result in the previous candidate location's failure. Matches may remain speculative for an extended period of time provided that the hardware is configured to support failure at different points during that speculative time. In response to detecting a speculative match failure, the enhanced encoder component 600 may perform a test to determine whether this is the longest match and whether it is greater than the minimum match. If so, the enhanced encoder component 600 may prune all current matches to start after this match's end and synthesize a new match from unused candidates of the speculative match. If not, the enhanced encoder component 600 may delete the speculative match, which may necessitate the synthesis of a new match from unused candidates of that speculative match. Since failed matches are typically replaced by a new candidate initiating a new match, these embodiments may include additional match slots during the match step to adhere to the algorithm. When a match becomes speculative due to its candidate failing, there will be a new unmatched candidate to start a match. This candidate may occupy the extra slot.

There could be restrictions on the number and duration of matches that could be speculative. For instance, there could be a maximum of three speculative match slots. Other failing matches would either need to be dropped, cause a stall, or replace one of the speculative match slots. Alternatively, there could be eight 1-cycle slots, three 2-cycle slots, and one 3-cycle slot. Completing a match to form a copy operation might be delayed due to late discovery of its end. This situation may be managed by adding more storage and logic to allow the matching step to run ahead of the entropy coding step. These enhancements may effectively remove history buffer check stalls, thereby enhancing throughput. In these embodiments, instead of carrying out speculative accesses to the history buffer, matches may initially be allowed to fail. Then the enhanced encoder component 600 may speculatively assume that the history buffer access is successful. This speculative approach includes maintaining the state as various speculative matches occur concurrently. Eventually, one of the history buffer checks may fail (despite the initial assumption of success), which may necessitate a reevaluation of the history to output the correct copy commands.

In some embodiments, the enhanced encoder component 600 may be configured to calculate the failure point in response to encountering a failure. In some embodiments, the enhanced encoder component 600 may be configured to determine whether the match was long enough after the original algorithm. In some embodiments, the enhanced encoder component 600 may be configured to not delete the other matches in response to determining that the match meets a length criterion (i.e., is long enough), and thus should be outputted. Instead, the enhanced encoder component 600 may adjust the ranges of the other matches to start after the match that is being admitted. By performing this adjustment process, the enhanced encoder component 600 may facilitate speculative history buffer checks and maintenance. Implementing this strategy may necessitate more range slots. If a history buffer check was assumed to be successful but in fact was not, the number of slots available for starting new matches is reduced by one. Therefore, extra slots may be needed to accommodate the speculative matches. The extra slots could be limited in a number of ways, such as restricting the extra slots to a maximum of three speculative slots at any time, or using a slot allocation system based on the number of cycles (e.g., eight 1-cycle slots, three 2-cycle slots, and one 3-cycle slot). If this strategy is adopted, the match output may be delayed, as may be the output of literals from the match process. This issue can be mitigated by allowing the match table to run ahead of the encoding process.

In some embodiments, the enhanced encoder component 600 may be configured to commence the encoding process by creating an initial pool of candidate matches based on the data and the system configuration. The enhanced encoder component 600 may perform matching operations for candidates that initially fail to match and preserve the unmatched candidates in a speculative state. That is, even though these candidates initially fail the match, the enhanced encoder component 600 may anticipate that they could succeed in the upcoming cycle.

In the next cycle, the enhanced encoder component 600 may perform a history buffer check on the unmatched candidates from the previous cycle. Simultaneously, the enhanced encoder component 600 may initiate the matching operations against a new candidate. During this cycle, the enhanced encoder component 600 may determine the success of a match based on whether a candidate passes both the history buffer check from the previous cycle and the current candidate match. The enhanced encoder component 600 may determine that the match failed if either of these checks fails.

The enhanced encoder component 600 may detect a speculative match failure. In response, the enhanced encoder component 600 may conduct a test to determine whether the failed match is the longest match and whether it surpasses the minimum match length. The enhanced encoder component 600 may prune all current matches to commence after the end of this match and synthesize a new match from the unused candidates of the speculative match in response to determine that the failed match passed the test.

If the failed match does not pass the test, the enhanced encoder component 600 may discard the speculative match, which may necessitate synthesizing a new match from unused candidates of the speculative match. When a match becomes speculative due to the failure of its candidate (i.e., the candidate initially didn't find a match in the current cycle), the enhanced encoder component 600 may start a match for a new unmatched candidate. The enhanced encoder component 600 may clear the slot previously occupied by the failed candidate to create an extra slot, which may then be occupied by a new unmatched candidate.

The enhanced encoder component 600 may impose restrictions on the number and duration of speculative matches. The enhanced encoder component 600 may limit speculative matches to a maximum of three speculative match slots, or alternatively, allow for eight 1-cycle slots, three 2-cycle slots, and one 3-cycle slot. The enhanced encoder component 600 may delay the completion of a match to form a copy operation due to late discovery of its end. To mitigate resulting delays, the enhanced encoder component 600 may incorporate additional storage and logic that allows the matching process to run ahead of the entropy coding process.

The enhanced encoder component 600 may output a match that has been verified and completed, as well as literals from the match process. The enhanced encoder component 600 may manage delays in the output by allowing the match table to run ahead of the encoding process. The enhanced encoder component 600 may reduce the number of slots available for initiating new matches and create additional slots to accommodate speculative matches if a history buffer check that was assumed successful is determined to be unsuccessful.

The enhanced encoder component 600 may maintain the state as various speculative matches occur concurrently, tracking each candidate's state and allowing for the appropriate handling of matches. The enhanced encoder component 600 may calculate the failure point, adjust match ranges, and initiate new matches in response to detecting a match failure.

The enhanced encoder component 600 may check to determine whether the match meets a length criterion (i.e., is long enough) according to the original algorithm. The enhanced encoder component 600 may forgo deleting other matches in response to determining that the match meets its length criterion and should be outputted. Rather, the enhanced encoder component 600 may adjust match ranges to commence after the match that is admitted. The enhanced encoder component 600 may repeat these operations for the entire input as the system continues processing new candidates, handling speculative matches, and outputting matches and literals.

The enhanced encoder component 600 may be equipped to modify the output based on speculative matches that were initially successful but eventually failed, resulting in an adjustment in the range of subsequent matches. This dynamic process assumes that the history buffer check will succeed, even when matches initially fail, allowing the system to maintain high throughput.

The enhanced encoder component 600 may provide extra match slots to accommodate speculative matches, with potential limitations on extra match slots, such as a maximum of three speculative slots at any time or employing a slot allocation system based on the number of cycles. The enhanced encoder component 600 may manage delayed output by allowing the match table to run ahead of the encoding.

In the example illustrated in FIG. 7, the encoder component 700 is fine-tuned to encode multiple bytes per cycle in parallel. With reference to FIGS. 1-7, the encoder component 700 may include a search table 502, a last X+3 704 component, a history buffer 506, a match table 508, a match stat-end 510 component, a coder 512, an entropy coder 514, a self-match 716 component, and a consistency filter 718 component.

In some embodiments, the encoder component 700 may be configured to accelerate data encoding in a computing system by: receiving multiple characters from an input data stream; performing a simultaneous look-up operation (through banking) for the received characters in a search table; managing any conflicts arising from the simultaneous look-up operation in which the multiple characters point to the same bank of the search table (e.g., by utilizing a system design that efficiently processes instances where multiple inputs point to the same character); generating up to four vectors from the search table based on the simultaneous look-up operation; pre-combining valid matches from the vectors into fewer match ranges using a consistency filter (the valid matches identified as those present across all vectors); extending the valid matches by up to four positions or based on a value of X (the extending may include checking match ranges instead of single candidates); encoding multiple symbols per cycle in parallel; checking end addresses of non-matches; and repeating the above operations until all of the input data in processed so that the encoding operations are performed on multiple bytes per cycle in parallel. The encoder component 700 may terminate the encoding process in response to determining that all input data has been processed and all matches and literals have been outputted. In some embodiments, pre-combining valid matches into fewer match ranges using the consistency filter may increase the throughput of the encoding process.

The encoder component 700 may accelerate the encoding process by checking the search table multiple times per cycle through banking. The encoder component 700 may be enhanced for an instance with multiple same-value inputs, which may introduce stalls due to conflicts. To manage conflicts, the encoder component 700 may use a consistency filter that pre-combines candidate matches into fewer match ranges before the matching step.

The encoder component 700 may include a code selection and entropy encoder (entropy coder 514) that is configured to handle multiple symbols per cycle by coding symbols in parallel. The encoder component 700 may be configured to check the end addresses of non-matches. The number of matches may remain the same, but the matches may be longer.

The encoder component 700 may operate as a multi-encoder system, encoding multiple bytes per cycle by conducting history searches in parallel. The encoder component 700 may take multiple characters from the input (e.g., four characters) and look them up simultaneously in the search table via banking. Since conflicts could arise if different characters point to the same bank (leading to stalls), the encoder component 700 may be configured to utilize a system design that efficiently handles instances in which multiple inputs point to the same character.

The encoder component 700 may output up to four vectors from the search table after a search operation. The encoder component 700 may use a consistency filter to pre-condense valid matches present across all vectors into a series of ranges. The encoder component 700 may extend matches up to four positions at a time or according to the value of the current match, thereby checking ranges of matches rather than single candidates. The encoder component 700 may offer a more efficient way to extend match ranges and thus may significantly speed up the encoding operations.

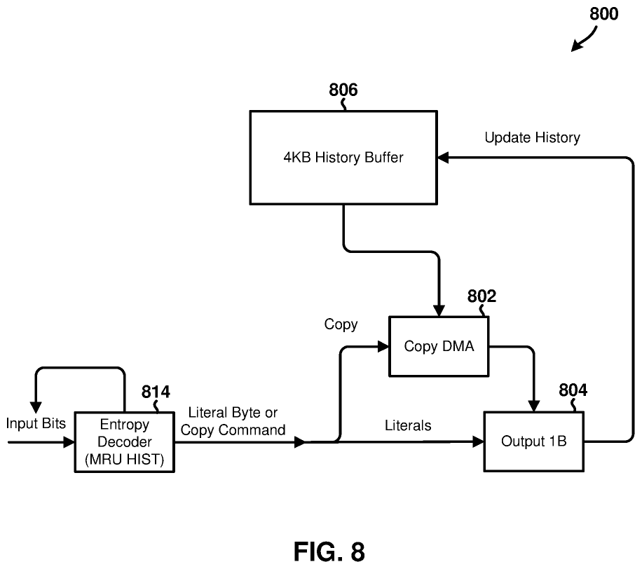

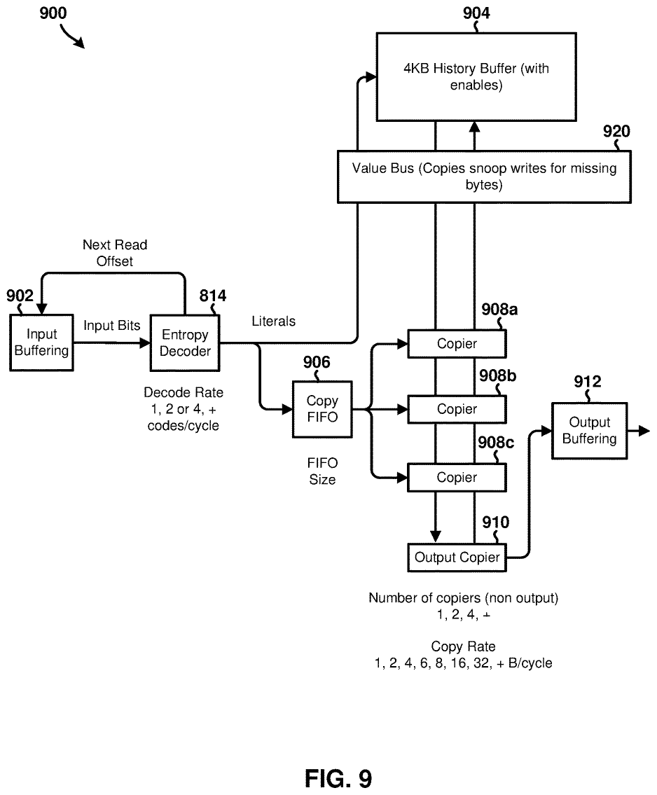

FIGS. 8 and 9 illustrate example decoder circuits, components or devices that are suitable for performing enhanced compression operations in accordance with various embodiments. In the example illustrated in FIG. 8, the decoder component 800 may be configured to perform enhanced decompression operations in accordance with some embodiments. In the example illustrated in FIG. 9, the decoder component 900 is fine-tuned for multiple bytes per cycle in parallel for the decode operation.

With reference to FIGS. 1-8, FIG. 8 illustrates an implementation in which the decoder component 800 may include a copy DMA 802 component, an output 1B 804 component, a history buffer 806, and an entropy decoder 814.

With reference to FIGS. 1-9, FIG. 9 illustrates an implementation in which the decoder component 900 may include an input buffering 902 component, a history buffer (with enables) 904, an entropy decoder 814, a copy FIFO 906 component, a plurality of copier 908a-c components, an output copier 910 component, an output buffering 912 component, and a value bus 920 component that is configured to copy snoop writes for missing bytes.

The decoder component 900 may implement an accelerated process for handling copies in a decoder that can manage 4 to 18+B per cycle. The decoder component 900 may use pipelining for faster decoding. The decoder component 900 may use the copy FIFO 906 to provide time for literals to pre-populate the history buffer 904. The decoder component 900 may be configured to manage multiple copiers 908 operating simultaneously. A single decode cycle and copier engine 910 may sustain close to 4B/cycle, and the history buffer 904 and value bus 920 may be highly banked to avoid conflicts. Each byte in the copy_rate bytes may be independent and may be individually banked and/or each copy_rate “word” may include byte enables on a larger bus. Further, copier 908a-c may copy B at an interleaved width to simplify memory access and reduce dependencies, meeting the B/cycle requirement.

The decoder component 900 may be configured to decode multiple symbols per cycle, which may necessitate the writing out of multiple copies or literals every cycle. The literals may be written immediately into the history buffer 904, potentially up to X literals per cycle. Copies may be stored in a FIFO to delay other writes into the history buffer 904. Multiple copier 908a-c engines may select copy commands from the FIFO as they finish their current task. These commands may execute a copy by reading from the history buffer 904 and writing back into it.

In some embodiments, the decoder component 900 may be configured to address complications that may arise when a copier 908a-c waits for a byte to be written into the history buffer 904. For example, the decoder component 900 may include a status indicator that indicates whether a byte is valid in the history buffer 904. If a copier 908a-c is waiting for another copier 908a-c to finish writing that line, the waiting copier 908a-c may Snoop for the write to the address it is waiting for, which may enable the waiting copier to continue copying when the other copier 908a-c writes back to the history buffer 904.

Each copier 908a-c may include its own state machine. Each copier 908a-c may determine the address it needs to copy and execute the read. If the read operation is not valid or has not been written, the copier 908a-c may wait and listen for it on the bus. The decoder component 900 may handle up to 14 to 16 bytes per cycle with four copier 908a-cs. The decoder component 900 may be configured to write back to the history buffer 904 as soon as possible, enabling it to be used by another copier 908a-c and ensuring maximum speed. The decoder component 900 may include a special output copier 910 component that carries a command that takes the start of the buffer and copies it to the output rather than back into the history buffer 904. If the copier 908a-c runs out of valid data in the history buffer 904, it may stall until another copier 908a-c writes back into the history buffer 904.

The output copier 910 component may produce uncompressed data, pulling such data from the history buffer 904, which may be a different buffer from the encoding buffer. When the decoder component 900 is finished with a page, it may include the same contents due to it storing the same uncompressed buffer in the history buffer 904. However, the way the page is constructed may be different since the decoder component 900 decompresses it into the history buffer 904, while the encoding operations append the input characters directly to the end of the buffer.

While various embodiments are particularly well suited for use in a ZRAM acceleration engine or a direct memory access (DMA) system that takes in data and outputs compressed data, the embodiments may be used to improve any bulk compression operations. Some embodiments may be incorporated into the inline encoder and connected to an encryptor to compress memory on writes, and/or in the decoder for reads from ZRAM.

In some embodiments, the decoder component 900 component may be configured to accelerate decoding in a computing device by initializing a plurality of copier engines and a first-in-first-out (FIFO) queue, setting up a history buffer for writing and reading data, and decoding multiple symbols per cycle. For each decoded symbol, the decoder component 900 may: determine whether the symbol is a literal or a copy command; write the symbol immediately into the history buffer if the symbol is a literal, and enqueue the symbol into the FIFO if the symbol is a copy command. The decoder component 900 may cause each available copier engine to dequeue a copy command while the FIFO is not empty. For each dequeued copy command, the decoder component 900 may: read a source address from the history buffer using the copier engine, check the validity of data at the source address in the history buffer; copy the data from the source address to a target address in the history buffer in response to determining that the data is valid; and stall the copier engine and have it snoop on the source address if the data at the source address in response to determining that the data is not valid. If a copier engine stalls because it is waiting for another copier to finish writing, the decoder component 900 may cause the stalled copier engine to snoop on the write address in the history buffer. The decoder component 900 may resume the copy operation of the stalled copier engine once the other copier writes data back to the source address in the history buffer. The decoder component 900 may deploy a special output copier that: copies data from the start of the history buffer to an output (rather than back into the history buffer); stalls the output copier if it runs out of valid data in the history buffer (and causes it to wait until another copier writes back into the history buffer); cause the output copier to snoop for writes to the addresses that it is waiting for in the history buffer and continue copying after the writes are completed; continue the decoding of symbols and executing of copy commands until all symbols are processed, flushing any remaining copy commands in the FIFO once all symbols are processed; and reconfigure the decoding system so that it is ready for another decoding task after flushing the FIFO.

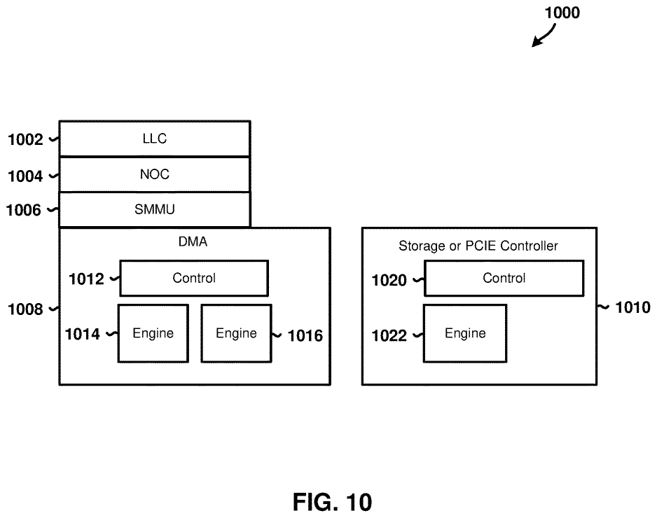

FIG. 10 illustrates example components in a processing system 1000 suitable for implementing page compression hardware integration in accordance with some embodiments. With reference to FIGS. 1-10, the processing system 1000 may include an LLC 1002 component, an NOC 1004 component, an SMMU 1006 component, a DMA 1008 component, and a storage or PCIE controller 1010. The DMA 1008 may include a controller 1012 and a plurality of engines 1014, 1016. The storage or PCIE controller 1010 may include a controller 1020 and an engine 1022.

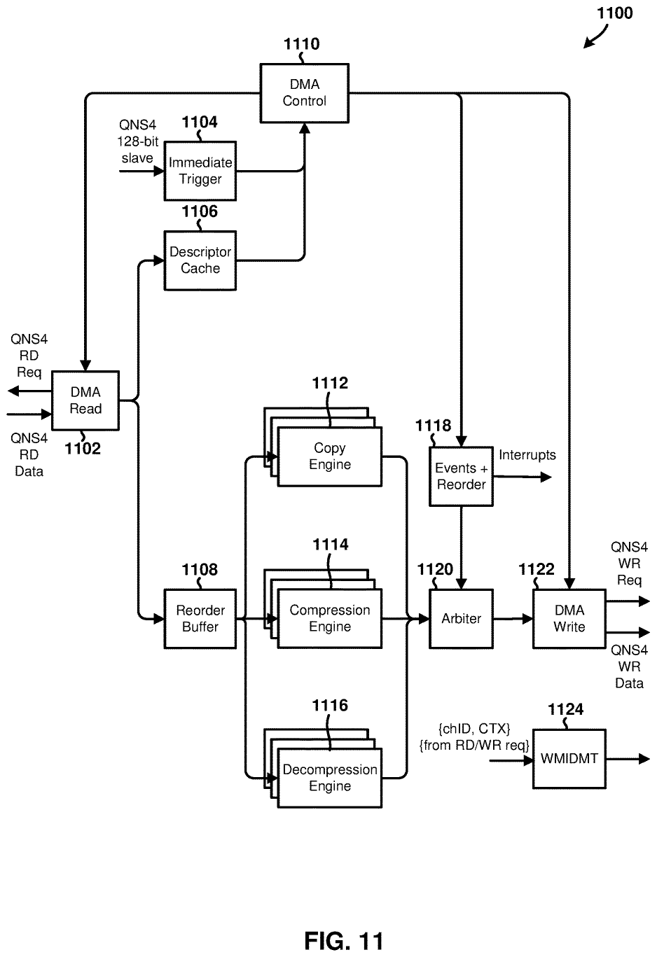

FIG. 11 illustrates an example of page compression software and/or hardware architecture in a processing system 1100 that may be configured to perform compression and/or decompression operations in accordance with some embodiments. With reference to FIGS. 1-11, the processing system 1100 may include a DMA read 1102 component, an immediate trigger 1104, descriptor cache 1106, reorder buffer 1108, DMA controller 1110, one or more copy engines 1112, one or more compression engines 1114, one or more decompression engines, an events +reorder 1118 component, an arbiter 1120 component, a DMA write 1122 component, and a WMIDMT 124 component.

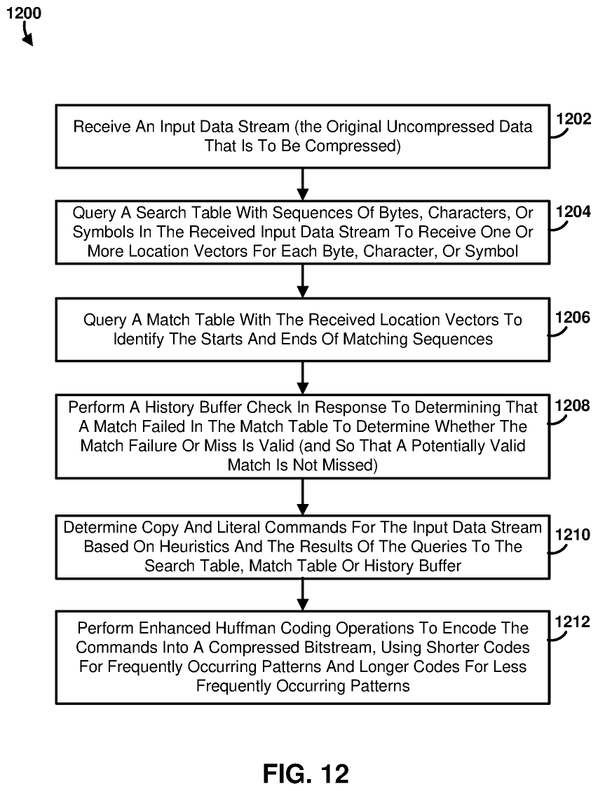

FIG. 12 illustrates a method 1200 for performing data compression according to various embodiments. With reference to FIGS. 1-12, means for performing the method 1200 may include a processing system as described herein. A processing system may include one or more processors (e.g., 210, 212, 214, 216, 218, 252, 260, 306, 316, 330) and/or hardware elements, any one or combination of which may be configured to perform any of the operations of the method 1200. Further, one or more processors within a processing system may be configured with software or firmware, to perform various operations of the method. To encompass any of the processor(s), hardware elements and software element that may be involved in performing the method 1200, the element(s) performing method operations are referred to generally as a “processing system.”

In block 1202, the processing system may receive an input data stream (the original uncompressed data that is to be compressed).

In block 1204, the processing system may query a search table with sequences of bytes, characters, or symbols in the received input data stream to receive one or more location vectors for each byte, character, or symbol.

In block 1206, the processing system may query a match table with the received location vectors to identify the starts and ends of matching sequences. In some embodiments, querying the match table with the received location vectors to identify the starts and ends of matching sequences may include querying the match table to identify sequences in the input data stream that match previously identified sequences based on the locations indexed in the search table.

In block 1208, the processing system may perform a history buffer check in response to determining that a match failed in the match table to determine whether the match failure or miss is valid (and so that a potentially valid match is not missed). In some embodiments, performing such a history buffer check in block 1208 may include determining a current position in the match table being checked for repeated sequences, and performing the history buffer check based on whether a current position in the match table is less than the last index of the search table. In some embodiments, performing such a history buffer check in block 1208 may include determining a current position in the match table being checked for repeated sequences, determining whether the current position is within a range that was already covered by the search table, and forgoing performing the history buffer check in response to determining that the current position in the match table is less than the value of the last index of the search table. In some embodiments, performing such a history buffer check in block 1208 may include determining a current position in the match table being checked for repeated sequences, determining whether the current position is less than the value of the search table[last index], determining whether a search table valid flag[last index] is set, and performing the history buffer check in response to determining that the position in the match table is less than the value of search table[last index] and that the search table valid flag[last index] has been set. In some embodiments, performing such a history buffer check in block 1208 may include searching portions of the history buffer that correspond to the indexes that were miss by the search table for each location that does not match a previously identified sequence in match table to verify that the match was not missed in the search table.

In some embodiments, performing a history buffer check in response to determining that the match failed in the match table to determine whether the match failure or miss is valid in block 1208 may include using a heuristic to speculatively access the history buffer in parallel with the match table query to preemptively fetch the data and reduce potential delays that are due to the order in which instructions are executed by hardware. In such embodiments, the search table may store a static vector for each sequence that represent the historical locations in which the sequence has previously been encountered in the data stream, the search table may implement a rolling window of history in which the oldest location in the vector is removed when the vector is full and a new occurrence of sequence is encountered, and performing the history buffer check may include determining a current position in the match table being checked for repeated sequences, determining whether the vector in the search table for the sequence character has been filled, determining that every instance of that character in the data stream up until the current position is recorded in the search table in response to determining that the vector in the search table for sequence has not been filled, and forgoing performing the history buffer check in response to determining that every instance of that character in the data stream up until the current position is recorded in the search table.

In block 1210, the processing system may determine copy and literal commands for the input data stream based on heuristics and the results of the queries to the search table, match table or history buffer.

In block 1212, the processing system may perform enhanced Huffman coding operations to encode the commands into a compressed bitstream, using shorter codes for frequently occurring patterns and longer codes for less frequently occurring patterns.

Various embodiments illustrated and described are provided merely as examples to illustrate various features of the claims. However, features shown and described with respect to any given embodiment are not necessarily limited to the associated embodiment and may be used or combined with other embodiments that are shown and described. Further, the claims are not intended to be limited by any one example embodiment.

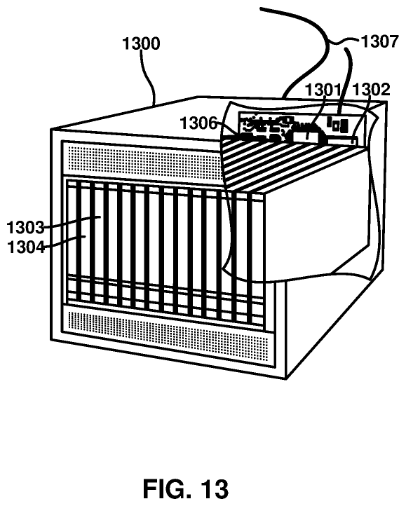

Some embodiments may be implemented on any of a variety of commercially available computing devices, such as the server computing device 1300 illustrated in FIG. 13. Such a server device 1300 may include a processor 1301 coupled to volatile memory 1302 and a large capacity nonvolatile memory, such as a disk drive 1303. The server device 1300 may also include a floppy disc drive, USB, etc. coupled to the processor 1301. The server device 1300 may also include network access ports 1306 coupled to the processor 1301 for establishing data connections with a network connection circuit 1304 and a communication network (e.g., IP network) coupled to other communication system network elements.

The processing systems discussed in this application may include one or more of any programmable microprocessor, microcomputer or multiple processor chip or chips that can be configured by software instructions (applications) to perform a variety of functions, including the functions of the various embodiments described above. In some devices, multiple processors may be provided, such as one processor dedicated to wireless communication functions and one processor dedicated to running other applications. Typically, software applications may be stored in the internal memory before application software is accessed and loaded into the processors. The processing system may include internal memory sufficient to store the application software instructions. In many devices, the internal memory may be a volatile or nonvolatile memory, such as flash memory, or a mixture of both. For the purposes of this description, a general reference to memory refers to memory accessible by the processors including internal memory or removable memory plugged into the device and memory within the processors themselves. Additionally, as used herein, any reference to a memory may be a reference to a memory storage and the terms may be used interchangeably.

A number of different types of memories and memory technologies are available or contemplated in the future, any or all of which may be included and used in systems and computing devices that implement the various embodiments. Such memory technologies/types may include non-volatile random-access memories (NVRAM) such as Magnetoresistive RAM (M-RAM), resistive random access memory (ReRAM or RRAM), phase-change random-access memory (PC-RAM, PRAM or PCM), ferroelectric RAM (F-RAM), spin-transfer torque magnetoresistive random-access memory (STT-MRAM), and three-dimensional cross point (3D-XPOINT) memory. Such memory technologies/types may also include non-volatile or read-only memory (ROM) technologies, such as programmable read-only memory (PROM), field programmable read-only memory (FPROM), one-time programmable non-volatile memory (OTP NVM). Such memory technologies/types may further include volatile random-access memory (RAM) technologies, such as dynamic random-access memory (DRAM), double data rate (DDR) synchronous dynamic random-access memory (DDR SDRAM), static random-access memory (SRAM), and pseudostatic random-access memory (PSRAM). Systems and computing devices that implement the various embodiments may also include or use electronic (solid-state) non-volatile computer storage mediums, such as FLASH memory. Each of the above-mentioned memory technologies include, for example, elements suitable for storing instructions, programs, control signals, and/or data for use in or by a computing device's processing system, system on chip (SOC) or other electronic component. Any references to terminology and/or technical details related to an individual type of memory, interface, standard or memory technology are for illustrative purposes only, and not intended to limit the scope of the claims to a particular memory system or technology unless specifically recited in the claim language.

Implementation examples are described in the following paragraphs. While some of the following implementation examples are described in terms of example methods, further example implementations may include: the example methods discussed in the following paragraphs implemented by a computing device including a processor configured with processor-executable instructions to perform operations of the methods of the following implementation examples; the example methods discussed in the following paragraphs implemented by a computing device including means for performing functions of the methods of the following implementation examples; and the example methods discussed in the following paragraphs may be implemented as a non-transitory processor-readable storage medium having stored thereon processor-executable instructions configured to cause a processor of a computing device to perform the operations of the methods of the following implementation examples.
Example 1: A method performed by one or more processors of computing device that includes performing enhanced coding operations, including receiving an input data stream, querying a search table with sequences of bytes, characters, or symbols in the received input data stream to receive one or more location vectors for each byte, character, or symbol, querying a match table with the received location vectors to identify the starts and ends of matching sequences, performing a history buffer check in response to determining that a match failed in the match table to determine whether the match failure or miss is valid, determining copy and literal commands for the input data stream based on heuristics and the results of the queries to the search table, the match table, or the history buffer, and performing enhanced Huffman coding operations to encode the copy and literal commands into a compressed bitstream, using shorter codes for frequently occurring patterns and longer codes for less frequently occurring patterns.
Example 2: The method of example 1, in which performing the history buffer check in response to determining that the match failed in the match table to determine whether the match failure or miss is valid includes determining a current position in the match table being checked for repeated sequences, and performing the history buffer check based on whether the current position in the match table is less than a last index of the search table.
Example 3: The method of any of examples 1 and 2, in which performing the history buffer in response to determining that the match failed in the match table to determine whether the match failure or miss is valid includes determining a current position in the match table being checked for repeated sequences, determining whether the current position is within a range that was already covered by the search table, and forgoing performing the history buffer check in response to determining that the current position in the match table is less than a value of a last index of the search table.
Example 4: The method of any of examples 1-3, in which performing the history buffer check in response to determining that the match failed in the match table to determine whether the match failure or miss is valid includes determining a current position in the match table being checked for repeated sequences, determining whether the current position is less than a value of the search table[last index], determining whether a search table valid flag[last index] is set, and performing the history buffer check in response to determining that a position in the match table is less than the value of search table[last index] and that the search table valid flag[last index] has been set.
Example 5: The method of any of examples 1-4, in which the search table stores a static vector for each sequence that represent historical locations in which the sequence has previously been encountered in the input data stream, the search table implements a rolling window of history in which oldest location in the static vector is removed when the vector is full and a new occurrence of sequence is encountered, and performing the history buffer check in response to determining that the match failed in the match table to determine whether the match failure or miss is valid includes determining a current position in the match table being checked for repeated sequences, determining whether the static vector in the search table for a sequence character has been filled, determining that every instance of that character in the input data stream up until the current position is recorded in the search table in response to determining that the static vector in the search table for sequence has not been filled, and forgoing performing the history buffer check in response to determining that every instance of that character in the input data stream up until the current position is recorded in the search table.
Example 6: The method of any of examples 1-6, in which performing the history buffer check in response to determining that the match failed in the match table to determine whether the match failure or miss is valid includes using a heuristic to speculatively access the history buffer in parallel with the match table query to preemptively fetch data and reduce potential delays that are due to an order in which instructions are executed by hardware.
Example 7: The method of example 6, in which using the heuristic to speculatively access the history buffer in parallel with the match table query to preemptively fetch the data and reduce potential delays that are due to the order in which instructions are executed by hardware includes prioritizing checking oldest matches first, and prioritizing checking newest matches in response to determining that the match table query failed to identify the match.
Example 8: The method of any of examples 1-7, in which querying the match table with the received location vectors to identify starts and ends of matching sequences includes querying the match table to identify sequences in the input data stream that match previously identified sequences based on locations indexed in the search table, and performing the history buffer check in response to determining that the match failed in the match table to determine whether the match failure or miss is valid includes searching portions of the history buffer that correspond to indexes that were miss by the search table for each location that does not match a previously identified sequence in the match table to verify that the match was not missed in the search table.
Example 9: The method of any of examples 1-8, further including improving efficiency of hardware decoding operations by generating enhanced Huffman tables that constrain Huffman codes to only sequences that include a series of all zeros or a series of zeros followed by a single one.
Example 10: The method of example 9, further including using a most recently used (MRU) table to keep track of recently used literals and using a special code to index into the MRU table to reduce the size of each literal by two bits.
Example 11: The method of example 9, further including using a most recently used (MRU) table to keep track of recently used copy distances in copy commands and accessing frequently used copy distances from the MRU table.

The foregoing method descriptions and the process flow diagrams are provided merely as illustrative examples and are not intended to require or imply that the steps of the various embodiments must be performed in the order presented. As will be appreciated by one of skill in the art the order of steps in the foregoing embodiments may be performed in any order. Words such as “thereafter,” “then,” “next,” etc. are not intended to limit the order of the steps; these words are simply used to guide the reader through the description of the methods. Further, any reference to claim elements in the singular, for example, using the articles “a,” “an” or “the” is not to be construed as limiting the element to the singular.

As used in this application, the terms “component,” “comparator,” “encoder,” “element” “system,” and the like are intended to include a computer-related entity, such as, but not limited to, hardware, firmware, a combination of hardware and software, software, or software in execution, which are configured to perform particular operations or functions. For example, a component may be, but is not limited to, a process running on a processor, a processor, an object, an executable, a thread of execution, a program, and/or a computer. By way of illustration, both an application running on a computing device and the computing device may be referred to as a component. One or more components may reside within a process and/or thread of execution, and a component may be localized on one processor or core and/or distributed between two or more processors or cores. In addition, these components may execute from various non-transitory computer readable media having various instructions and/or data structures stored thereon. Components may communicate by way of local and/or remote processes, function or procedure calls, electronic signals, data packets, memory read/writes, and other known network, computer, processor, and/or process related communication methodologies.

The various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the claims.

The hardware used to implement the various illustrative logics, logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a multiprocessor, but, in the alternative, the processor may be any conventional processor, controller, microcontroller, or state machine. A processor may also be implemented as a combination of computing devices, e.g., a combination of a DSP and a multiprocessor, a plurality of multiprocessors, one or more multiprocessors in conjunction with a DSP core, or any other such configuration. Alternatively, some steps or methods may be performed by circuitry that is specific to a given function.

In one or more exemplary embodiments, the functions described may be implemented in hardware, software, firmware, or any combination thereof. If implemented in software, the functions may be stored as one or more processor-executable instructions or code on a non-transitory computer-readable storage medium or non-transitory processor-readable storage medium. The steps of a method or algorithm disclosed herein may be embodied in a processor-executable software module, which may reside on a non-transitory computer-readable or processor-readable storage medium. Non-transitory computer-readable or processor-readable storage media may be any storage media that may be accessed by a computer or a processor. By way of example but not limitation, such non-transitory computer-readable or processor-readable media may include RAM, ROM, EEPROM, FLASH memory, CD-ROM or other optical disk storage, magnetic disk storage or other magnetic storage devices, or any other medium that may be used to store desired program code in the form of instructions or data structures and that may be accessed by a computer. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above are also included within the scope of non-transitory computer-readable and processor-readable media. Additionally, the operations of a method or algorithm may reside as one or any combination or set of codes and/or instructions on a non-transitory processor-readable medium and/or computer-readable medium, which may be incorporated into a computer program product.

The preceding description of the disclosed embodiments is provided to enable any person skilled in the art to make or use the claims. Various modifications to these embodiments will be readily apparent to those skilled in the art, and the generic principles defined herein may be applied to other embodiments without departing from the scope of the claims. Thus, the claims are not intended to be limited to the embodiments shown herein but are to be accorded the widest scope consistent with the following claims and the principles and novel features disclosed herein.

1. A method of performing enhanced coding operations, comprising:
receiving an input data stream;
querying a search table with sequences of bytes, characters, or symbols in the received input data stream to receive one or more location vectors for each byte, character, or symbol;
querying a match table with the received location vectors to identify the starts and ends of matching sequences;
performing a history buffer check in response to determining that a match failed in the match table to determine whether the match failure or miss is valid;
determining copy and literal commands for the input data stream based on heuristics and the results of the queries to the search table, the match table, or the history buffer; and
performing enhanced Huffman coding operations to encode the copy and literal commands into a compressed bitstream, using shorter codes for frequently occurring patterns and longer codes for less frequently occurring patterns.

2. The method of claim 1, wherein performing the history buffer check in response to determining that the match failed in the match table to determine whether the match failure or miss is valid comprises:
determining a current position in the match table being checked for repeated sequences; and
performing the history buffer check based on whether the current position in the match table is less than a last index of the search table.

3. The method of claim 1, wherein performing the history buffer in response to determining that the match failed in the match table to determine whether the match failure or miss is valid comprises:
determining a current position in the match table being checked for repeated sequences;
determining whether the current position is within a range that was already covered by the search table; and
forgoing performing the history buffer check in response to determining that the current position in the match table is less than a value of a last index of the search table.

4. The method of claim 1, wherein performing the history buffer check in response to determining that the match failed in the match table to determine whether the match failure or miss is valid comprises:
determining a current position in the match table being checked for repeated sequences;
determining whether the current position is less than a value of the search table[last index];
determining whether a search table valid flag[last index] is set; and
performing the history buffer check in response to determining that a position in the match table is less than the value of search table[last index] and that the search table valid flag[last index] has been set.

5. The method of claim 1, wherein:
the search table stores a static vector for each sequence that represent historical locations in which the sequence has previously been encountered in the input data stream;
the search table implements a rolling window of history in which oldest location in the static vector is removed when the vector is full and a new occurrence of sequence is encountered; and
performing the history buffer check in response to determining that the match failed in the match table to determine whether the match failure or miss is valid comprises:
determining a current position in the match table being checked for repeated sequences;
determining whether the static vector in the search table for a sequence character has been filled;
determining that every instance of that character in the input data stream up until the current position is recorded in the search table in response to determining that the static vector in the search table for sequence has not been filled; and
forgoing performing the history buffer check in response to determining that every instance of that character in the input data stream up until the current position is recorded in the search table.

6. The method of claim 1, wherein performing the history buffer check in response to determining that the match failed in the match table to determine whether the match failure or miss is valid comprises using a heuristic to speculatively access the history buffer in parallel with the match table query to preemptively fetch data and reduce potential delays that are due to an order in which instructions are executed by hardware.

7. The method of claim 6, wherein using the heuristic to speculatively access the history buffer in parallel with the match table query to preemptively fetch the data and reduce potential delays that are due to the order in which instructions are executed by hardware comprises:
prioritizing checking oldest matches first; and
prioritizing checking newest matches in response to determining that the match table query failed to identify the match.

8. The method of claim 1, wherein:
querying the match table with the received location vectors to identify starts and ends of matching sequences comprises querying the match table to identify sequences in the input data stream that match previously identified sequences based on locations indexed in the search table; and
performing the history buffer check in response to determining that the match failed in the match table to determine whether the match failure or miss is valid comprises searching portions of the history buffer that correspond to indexes that were miss by the search table for each location that does not match a previously identified sequence in the match table to verify that the match was not missed in the search table.

9. The method of claim 1, further comprising improving efficiency of hardware decoding operations by generating enhanced Huffman tables that constrain Huffman codes to only sequences that include a series of all zeros or a series of zeros followed by a single one.

10. The method of claim 9, further comprising:
using a most recently used (MRU) table to keep track of recently used literals; and
using a special code to index into the MRU table to reduce a size of each literal by two bits.

11. The method of claim 9, further comprising:
using a most recently used (MRU) table to keep track of recently used copy distances in copy commands; and
accessing frequently used copy distances from the MRU table.

12. A computing device, comprising
an enhanced coding component configured to:
receive an input data stream;
query a search table with sequences of bytes, characters, or symbols in the received input data stream to receive one or more location vectors for each byte, character, or symbol;
query a match table with the received location vectors to identify the starts and ends of matching sequences;
perform a history buffer check in response to determining that a match failed in the match table to determine whether the match failure or miss is valid;
determine copy and literal commands for the input data stream based on heuristics and the results of the queries to the search table, the match table, or the history buffer; and
perform enhanced Huffman coding operations to encode the copy and literal commands into a compressed bitstream, using shorter codes for frequently occurring patterns and longer codes for less frequently occurring patterns.

13. The computing device of claim 12, wherein the enhanced coding component is configured to perform the history buffer check in response to determining that the match failed in the match table to determine whether the match failure or miss is valid by:
determining a current position in the match table being checked for repeated sequences; and
performing the history buffer check based on whether the current position in the match table is less than a last index of the search table.

14. The computing device of claim 12, wherein the enhanced coding component is configured to perform the history buffer in response to determining that the match failed in the match table to determine whether the match failure or miss is valid by:
determining a current position in the match table being checked for repeated sequences;
determining whether the current position is within a range that was already covered by the search table; and
forgoing performing the history buffer check in response to determining that the current position in the match table is less than a value of a last index of the search table.

15. The computing device of claim 12, wherein the enhanced coding component is configured to perform the history buffer check in response to determining that the match failed in the match table to determine whether the match failure or miss is valid comprises:
determining a current position in the match table being checked for repeated sequences;
determining whether the current position is less than a value of the search table[last index];
determining whether a search table valid flag[last index] is set; and
performing the history buffer check in response to determining that a position in the match table is less than the value of search table[last index] and that the search table valid flag[last index] has been set.

16. The computing device of claim 12, wherein the enhanced coding component is configured such that:
the search table stores a static vector for each sequence that represent historical locations in which the sequence has previously been encountered in the input data stream;
the search table implements a rolling window of history in which oldest location in the static vector is removed when the vector is full and a new occurrence of sequence is encountered; and
performing the history buffer check in response to determining that the match failed in the match table to determine whether the match failure or miss is valid comprises:
determining a current position in the match table being checked for repeated sequences;
determining whether the static vector in the search table for a sequence character has been filled;
determining that every instance of that character in the input data stream up until the current position is recorded in the search table in response to determining that the static vector in the search table for sequence has not been filled; and
forgoing performing the history buffer check in response to determining that every instance of that character in the input data stream up until the current position is recorded in the search table.

17. The computing device of claim 12, wherein the enhanced coding component is configured to perform the history buffer check in response to determining that the match failed in the match table to determine whether the match failure or miss is valid by using a heuristic to speculatively access the history buffer in parallel with the match table query to preemptively fetch data and reduce potential delays that are due to an order in which instructions are executed by hardware.

18. The computing device of claim 17, wherein the enhanced coding component is configured to use the heuristic to speculatively access the history buffer in parallel with the match table query to preemptively fetch the data and reduce potential delays that are due to the order in which instructions are executed by hardware by:
prioritizing checking oldest matches first; and
prioritizing checking newest matches in response to determining that the match table query failed to identify the match.

19. The computing device of claim 12, wherein the enhanced coding component is configured to:
query the match table with the received location vectors to identify starts and ends of matching sequences by querying the match table to identify sequences in the input data stream that match previously identified sequences based on locations indexed in the search table; and
perform the history buffer check in response to determining that the match failed in the match table to determine whether the match failure or miss is valid by searching portions of the history buffer that correspond to indexes that were miss by the search table for each location that does not match a previously identified sequence in the match table to verify that the match was not missed in the search table.

20. The computing device of claim 12, wherein the enhanced coding component is further configured to improve efficiency of hardware decoding operations by generating enhanced Huffman tables that constrain Huffman codes to only sequences that include a series of all zeros or a series of zeros followed by a single one.

21-40. (canceled)
